(19) United States
(12) Patent Application Publication
(10) Pub. No.: US 2024/0321976 A1
(43) Pub. Date: Sep. 26, 2024

(54) INTEGRATED CIRCUIT DEVICE AND METHOD OF MANUFACTURING THE SAME

(71) Applicant: Samsung Electronics Co., Ltd., Suwon-si (KR)

(72) Inventors: KANGUK KIM, Suwon-si (KR); DALHYEON LEE, Suwon-si (KR)

(21) Appl. No.: 18/413,172

(22) Filed: Jan. 16, 2024

(30) Foreign Application Priority Data
Mar. 24, 2023 (KR) 10-2023-0039191
May 24, 2023 (KR) 10-2023-0067139

(51) Int. Cl. H01L 29/417

(52) U.S. Cl. CPC H01L 29/41725

(57) ABSTRACT

An integrated circuit device includes a substrate including a plurality of active regions that include a first active region and a second active region that is adjacent to the first active region, a bit line that extends on the substrate in a horizontal direction, a first direct contact connected to the first active region, a second direct contact between the first direct contact and the bit line, an inner nitride film connected to a sidewall of the first direct contact and a sidewall of the second direct contact, an isolation film between the first active region and the second active region, and an outer oxide film that is connected to at least one surface of the second active region and between the inner nitride film and the second active region.

### CROSS-REFERENCE TO RELATED APPLICATIONS

This application is based on and claims priority under 35 U.S.C. § 119 to Korean Patent Application Nos. 10-2023-0039191, filed on Mar. 24, 2023 and 10-2023-0067139, filed on May 24, 2023, in the Korean Intellectual Property Office, the disclosures of which are incorporated by reference herein in their entirety.

### BACKGROUND

The present disclosure relates to an integrated circuit device and a method of manufacturing the same, and more particularly, to an integrated circuit device including a bit line and a method of manufacturing the same.

With the rapid development of down-scaling of integrated circuit devices, the gap between bit lines is decreasing and the distance between each of bit lines and another conductive region between the bit lines is also decreasing. Accordingly, conductive regions other than a conductive region connected to each of bit lines may be etched when the bit lines are formed, and therefore, a defect in which a contact plug is not connected to a conductive region may occur. Due to the short distance between a bit line and a contact plug, a defect in which the bit line is electrically connected to the contact plug may occur. It is desired to develop technology for implementing an integrated circuit device for preventing a defect, in which a contact plug is not connected to a conductive region, and maintaining a stable and reliable structure of bit lines.

### SUMMARY

The present disclosure provides an integrated circuit device for preventing a defect, in which a contact plug is not connected to a conductive region, and maintaining a stable and reliable structure of bit lines, even when the area of a device region is reduced according to a down-scaling of a semiconductor device, and a method of manufacturing the integrated circuit device.

According to an aspect of the present disclosure, an integrated circuit device includes a substrate that includes a plurality of active regions, where the plurality of active regions include a first active region and a second active region that is adjacent to the first active region; a bit line that extends on the substrate in a horizontal direction; a first direct contact connected to the first active region; a second direct contact between the first direct contact and the bit line; an inner nitride film connected to a sidewall of the first direct contact and a sidewall of the second direct contact; an isolation film between the first active region and the second active region; and an outer oxide film that is connected to at least one surface of the second active region and between the inner nitride film and the second active region.

According to another aspect of the present disclosure, an integrated circuit device includes a substrate that includes a plurality of active regions, where the plurality of active regions include a first active region and a second active region that is adjacent to the first active region; a plurality of bit lines on the substrate and separated from each other in a first horizontal direction, where the plurality of bit lines extend in a second horizontal direction that intersects the first horizontal direction; a first direct contact connected to the first active region; a second direct contact between the first direct contact and a first bit line from among the plurality of bit lines; a contact plug connected to the second active region and that extends in a vertical direction on an upper surface of the substrate; and a spacer structure between the first bit line and the contact plug, where the spacer structure includes: an inner nitride film connected to a sidewall of the first direct contact and a sidewall of the second direct contact; and an outer oxide film on the second active region in the vertical direction and connected to at least one surface of the second active region, and the outer oxide film is between the inner nitride film and the second active region.

According to another aspect of the present disclosure, an integrated circuit device includes a substrate that includes a first active region and a second active region; a bit line that extends on the substrate in a horizontal direction; a first direct contact connected to the first active region; a second direct contact between the first direct contact and the bit line; a contact plug connected to the second active region; and a spacer structure between the bit line and the contact plug, where the spacer structure includes: an inner nitride film connected to a sidewall of the first direct contact and a sidewall of the second direct contact; an inner insulating spacer connected to the inner nitride film; an outer oxide film on the second active region and connected to the second active region, where the outer oxide film is between the inner nitride film and the second active region; and a gapfill insulating pattern between the contact plug and the first direct contact.

According to still another aspect of the present disclosure, a method of manufacturing an integrated circuit device includes forming a plurality of word lines in a plurality of word line trenches of a substrate including a plurality of active regions, where the plurality of word lines extend in a first horizontal direction, and where the plurality of active regions include a first active region and a second active region that is adjacent to the first active region; forming a first direct contact hole by removing a portion of the substrate between the plurality of word lines and exposing the first active region the a second active region through the first direct contact hole; forming an outer oxide film on the first active region and the second active region; connecting the first direct contact hole to the first active region by removing the outer oxide film on the first active region; forming a first direct contact in the first direct contact hole; and forming a bit line connected to the first direct contact by stacking a plurality of conductive layers and an insulating capping pattern on the first direct contact and partially etching the plurality of conductive layers and the first direct contact by using the insulating capping pattern as an etch mask.

### BRIEF DESCRIPTION OF THE DRAWINGS

Embodiments will be more clearly understood from the following detailed description taken in conjunction with the accompanying drawings in which:

FIG. 1 is a schematic layout diagram illustrating a memory cell array region of an integrated circuit device according to embodiments of the present disclosure;

FIGS. 2A, 2B, and 2C shows cross-sectional views of an integrated circuit device according to embodiments of the present disclosure;

FIGS. 3A, 3B, 3C, 4A, 4B, 4C, 5A, 5B, and 5C are cross-sectional views of integrated circuit devices according to embodiments of the present disclosure; and

FIGS. 6A, 6B, 6C, 6D, 6E, 6F, 6G, 6H, 6I, 6J, 6K, 6L, 6M, 6N, 6O, 6P, 6Q, 6R, 6S, and 6T and FIGS. 7A, 7B, 7C, 7D, 7E, 7F, 7G, 7H, 7I, 7J, 7K, 7L, 7M, 7N, 7O, 7P, 7Q, 7R, 7S, and 7T are cross-sectional views of stages in a method of manufacturing an integrated circuit device according to embodiments of the present disclosure.

### DETAILED DESCRIPTION OF THE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection.

Hereinafter, embodiments are described in detail with reference to the accompanying drawings. In the drawings, like numerals denote like elements and redundant descriptions thereof will be omitted.

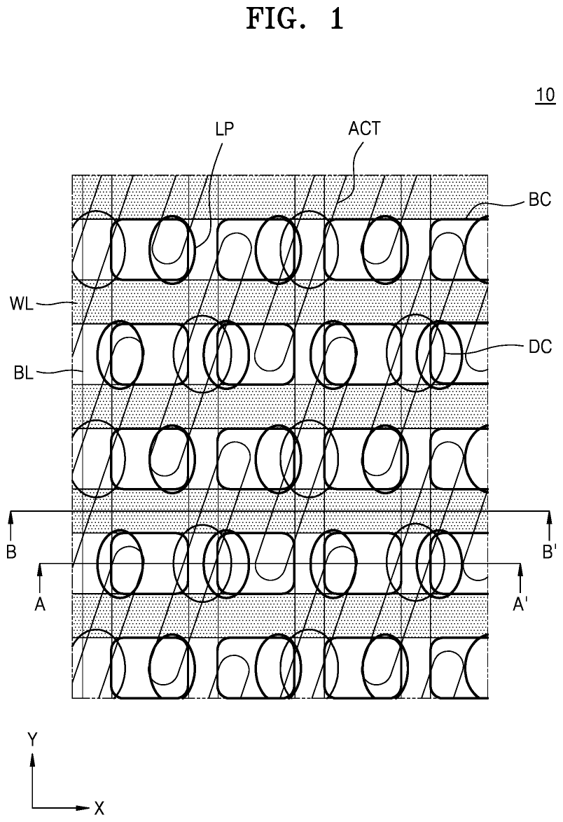

FIG. 1 is a schematic layout diagram illustrating main elements in a memory cell array region of an integrated circuit device according to embodiments of the present disclosure.

Referring to FIG. 1, an integrated circuit device 10 may include a plurality of active regions ACT. The active regions ACT may be arranged in a diagonal direction that is diagonal to a first horizontal direction (the X direction) and a second horizontal direction (the Y direction).

A plurality of word lines WL may extend across the active regions ACT in the first horizontal direction (the X direction) and may be parallel with each other. A plurality of bit lines BL may be above the word lines WL and parallel with each other and may extend in the second horizontal direction (the Y direction) that intersects the first horizontal direction (the X direction). Each of the bit lines BL may be connected to an active region ACT through a direct contact DC.

A plurality of buried contacts BC may be between two adjacent bit lines BL. According to embodiments, the buried contacts BC may be arranged in lines in the first horizontal direction (the X direction) and the second horizontal direction (the Y direction). A plurality of landing pads LP may be respectively on the buried contacts BC. Each of the buried contacts BC and each of the landing pads LP may connect a lower electrode (not shown) of a capacitor on one of the bit lines BL to one of the active regions ACT. Each of the landing pads LP may at least partially overlap with one of the buried contacts BC in a vertical direction.

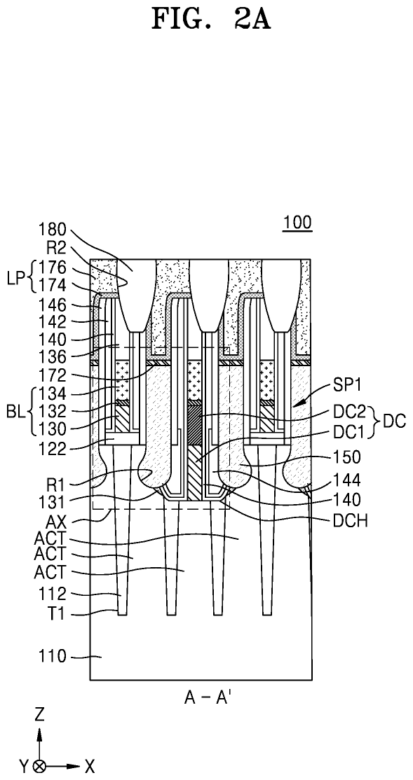

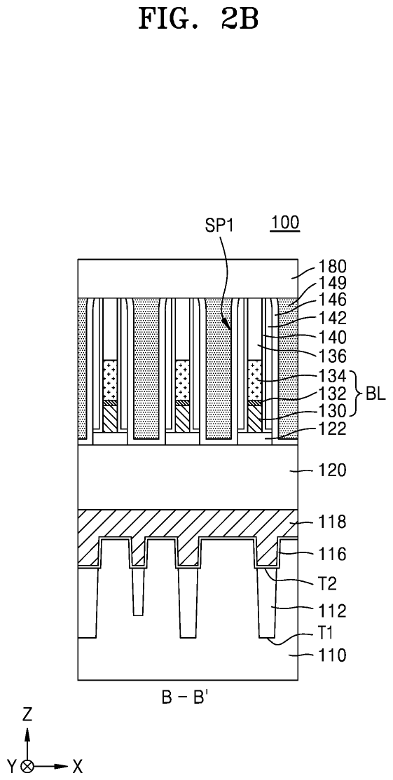

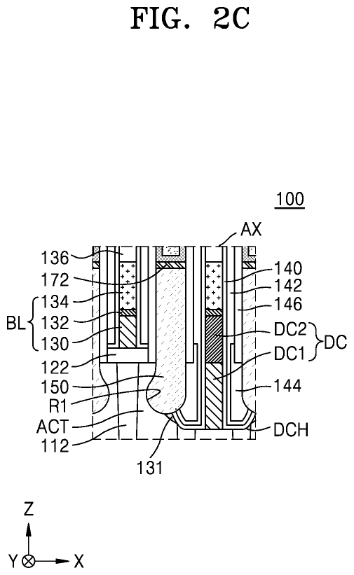

Example configurations of integrated circuit devices are described below with reference to FIGS. 2A-2C, 3A-3C, 4A-4C, and 5A-5C according to embodiments. Each of integrated circuit devices illustrated in FIGS. 2A-2C, 3A-3C, 4A-4C, and 5A-5C may have the layout of the integrated circuit device 10 of FIG. 1.

FIG. 2A is a cross-sectional view illustrating some elements of a portion corresponding to a cross-section along line A-A′ in FIG. 1, FIG. 2B is a cross-sectional view illustrating some elements of a portion corresponding to a cross-section along line B-B′ in FIG. 1, and FIG. 2C is an enlarged cross-sectional view of a portion corresponding to a dashed line region AX in FIG. 2A.

Referring to FIGS. 2A-2C, the integrated circuit device 100 may include a substrate 110 in which a plurality of active regions ACT are defined by an isolation film 112. The isolation film 112 may be formed in an isolation trench T1 formed in the substrate 110.

For example, the substrate 110 may include monocrystalline silicon, polycrystalline silicon, or amorphous silicon. According to some embodiments, the substrate 110 may include at least one of Ge, SiGe, SiC, GaAs, InAs, and InP. According to embodiments, the substrate 110 may include a conductive region, such as an impurity-doped well or an impurity-doped structure. The isolation film 112 may include an oxide film, a nitride film, or a combination thereof.

A plurality of word line trenches T2 may extend in the first horizontal direction (the X direction) in the substrate 110. A plurality of gate dielectric films 116, a plurality of word lines 118, and a buried insulating film 120 may be in the word line trenches T2. The word lines 118 may respectively correspond to the word lines WL in FIG. 1.

Each of the gate dielectric films 116 may include at least one of a silicon oxide film, a silicon nitride film, a silicon oxynitride film, an oxide/nitride/oxide (ONO) film, and a high-k dielectric film having a higher dielectric constant than the silicon oxide film. The high-k dielectric film may include HfO₂, Al₂O₃, HfAlO₃, Ta₂O₃, TiO₂, or a combination thereof. Each of the word lines 118 may include Ti, TiN, Ta, TaN, W, WN, TiSiN, WSiN, or a combination thereof. The buried insulating film 120 may include a silicon oxide film, a silicon nitride film, a silicon oxynitride film, or a combination thereof.

A buffer layer 122 is on the substrate 110. The buffer layer 122 may cover or overlap the top surfaces of the active regions ACT, the top surface of the isolation film 112, and the top surfaces of a plurality of buried insulating films 120. The buffer layer 122 may include, but is not limited to, a first silicon oxide film, a silicon nitride film, and a second silicon oxide film, which are sequentially formed on the substrate 110.

A plurality of bit lines BL may extend on the buffer layer 122 in the second horizontal direction (the Y direction) and may be parallel with each other. The bit lines BL may be separated from each other in the first horizontal direction (the X direction). A direct contact DC is on a portion of each of the active regions ACT. Each of the bit lines BL may be connected to one of the active regions ACT through the direct contact DC. The direct contact DC may include a first direct contact DC1, which is connected to a selected active region ACT among the active regions ACT, and a second direct contact DC2 between the first direct contact DC1 and one of the bit lines BL. Each of the first direct contact DC1 and the second direct contact DC2 may include Si, Ge, W, WN, Co, Ni, Al, Mo, Ru, Ti, TiN, Ta, TaN, Cu, or a combination thereof. In embodiments, the first direct contact DC1 or the second direct contact DC2 may include a doped polysilicon film.

Each of the bit lines BL may include a lower conductive layer 130, a middle conductive layer 132, and an upper conductive layer 134, which are sequentially formed on the substrate 110. Each of the bit lines BL may be covered with or overlapped by an insulating capping pattern 136. The insulating capping pattern 136 may be on the upper conductive layer 134 in the vertical direction (the Z direction). The top surface of the lower conductive layer 130 of each bit line BL may be coplanar with the top surface of the second direct contact DC2. Although it is illustrated in FIG. 2 that each of the bit lines BL has a triple-conductive layer structure including the lower conductive layer 130, the middle conductive layer 132, and the upper conductive layer 134, the present disclosure is not limited thereto. For example, each of the bit lines BL may have a single-conductive layer, a double-conductive layer, or a multi-conductive layer stack structure of at least four conductive layers.

In embodiments, the lower conductive layer 130 may include a doped polysilicon film. Each of the middle conductive layer 132 and the upper conductive layer 134 may include a film including Ti, TIN, TiSiN, tungsten (W), tungsten nitride (WN), tungsten silicide (WSiₓ), tungsten silicon nitride (WSiₓN_{y}), ruthenium (Ru), or a combination thereof. For example, the middle conductive layer 132 may include a TiN film and/or a TiSiN film and the upper conductive layer 134 may include a film including Ti, TiN, W, WN, WSiₓN_{y}, Ru, or a combination thereof. The insulating capping pattern 136 may include a silicon nitride film.

A plurality of contact plugs 150 may be on the substrate 110. Each of the contact plugs 150 may have a pillar shape, which extends in the vertical direction (the Z direction) in a space between bit lines BL. Each of the contact plugs 150 may be in contact with one of the active regions ACT. The bottom end of each of the contact plugs 150 may be at a lower level than the top surface of the substrate 110 so as to be buried in the substrate 110. The contact plugs 150 may include, but are not limited to, an impurity-doped semiconductor material, a metal, a conductive metal nitride, or a combination thereof.

In the integrated circuit device 100, one direct contact DC and a pair of contact plugs 150 facing each other with the direct contact DC therebetween may be respectively connected to different active regions ACT. In an embodiment, when a direct contact DC is connected to a first active region ACT selected from the plurality of active regions ACT, a pair of contact plugs 150 facing each other with the direct contact DC therebetween may be respectively connected to a second active region ACT and a third active region ACT, which are adjacent to the first active region ACT.

A plurality of contact plugs 150 may be arranged in line in the second horizontal direction (the Y direction) between two adjacent selected bit lines BL. An insulating fence 149 may be between two adjacent contact plugs 150 arranged in line in the second horizontal direction (the Y direction). The plurality of contact plugs 150 may be insulated from each other by a plurality of insulating fences 149. Each of the insulating fences 149 may have a pillar shape extending in the vertical direction (the Z direction) on the substrate 110. In embodiments, each of the insulating fences 149 may include a silicon nitride film.

The integrated circuit device 100 may include a plurality of spacer structures SP1 between the bit lines BL and the contact plugs 150. One spacer structure SP1 may be between one bit line BL and a plurality of contact plugs 150 arranged in line in the second horizontal direction (the Y direction). Each of the spacer structures SP1 may include an inner nitride film 140, an inner insulating spacer 142, a gapfill insulating pattern 144, and an outer insulating spacer 146.

The inner nitride film 140 may be in contact with a sidewall of the direct contact DC and a sidewall of the lower conductive layer 130 of a bit line BL. The inner nitride film 140 may be separated from a contact plug 150 by the outer insulating spacer 146. The inner nitride film 140 may include a portion in contact with the contact plug 150.

The inner nitride film 140 may extend in the vertical direction (the Z direction) along respective sidewalls of the middle conductive layer 132 and the upper conductive layer 134 of the bit line BL. The inner nitride film 140 may also extend along respective sidewalls of the middle conductive layer 132 and the upper conductive layer 134 that are on the direct contact DC. The inner nitride film 140 may include a portion between the direct contact DC and the gapfill insulating pattern 144. The inner nitride film 140 may cover or overlap opposite sidewalls of the insulating capping pattern 136 on the bit line BL and opposite sidewalls of the lower conductive layer 130 of the bit line BL from the highest level of the insulating capping pattern 136 to the lowest level of the lower conductive layer 130 in the vertical direction (the Z direction). The inner nitride film 140 may cover opposite sidewalls of the insulating capping pattern 136 on the direct contact DC and opposite sidewalls of the second direct contact DC2 of the direct contact DC from the highest level of the insulating capping pattern 136 to the lowest level of the second direct contact DC2 in the vertical direction (the Z direction). The inner nitride film 140 may include a nitride film, for example, a silicon nitride film.

The inner insulating spacer 142 may be in contact with the inner nitride film 140. The bottom surface of the inner insulating spacer 142 may be surrounded by the inner nitride film 140. The inner insulating spacer 142 may extend in the vertical direction (the Z direction) on the sidewall of the inner nitride film 140. The inner insulating spacer 142 may be between the bit line BL and the outer insulating spacer 146. The inner insulating spacer 142 may be separated from the bit line BL by the inner nitride film 140. The inner insulating spacer 142 may include a portion arranged between the direct contact DC and the gapfill insulating pattern 144. The inner insulating spacer 142 may include a portion in contact with the lower end portion of the contact plug 150. In an embodiment, the inner insulating spacer 142 may include an oxide film, for example, a silicon oxide film.

The gapfill insulating pattern 144 may be between the lower end portion of the contact plug 150 and the direct contact DC. A portion of the gapfill insulating pattern 144 facing the first direct contact DC1 may have a different thickness than a portion of the gapfill insulating pattern 144 facing the second direct contact DC2. In an embodiment, the portion of the gapfill insulating pattern 144 facing the first direct contact DC1 may be thicker than the portion of the gapfill insulating pattern 144 facing the second direct contact DC2. A sidewall of the gapfill insulating pattern 144 may be covered with or overlapped by the lower end portion of the contact plug 150. The other sidewall and bottom surface of the gapfill insulating pattern 144 may be surrounded by the inner insulating spacer 142. The inner nitride film 140 may surround the lower end portions of the inner insulating spacer 142 and the gapfill insulating pattern 144 and be in contact with the lower end portion of the contact plug 150. The inner insulating spacer 142 may surround the lower end portion of the gapfill insulating pattern 144 and be in contact with the lower end portion of the contact plug 150.

The outer insulating spacer 146 may cover or overlap a sidewall of the contact plug 150 adjacent thereto. The outer insulating spacer 146 may be arranged on the gapfill insulating pattern 144 and may cover or overlap the sidewall of the contact plug 150. The outer insulating spacer 146 may be between the contact plug 150 and the inner insulating spacer 142. The outer insulating spacer 146 may extend in the vertical direction (the Z direction), in which the sidewall of the bit line BL adjacent to the outer insulating spacer 146 extends. The outer insulating spacer 146 may be separated from the bit line BL by the inner nitride film 140 and the inner insulating spacer 142. The inner insulating spacer 142 may be surrounded by the outer insulating spacer 146 and the inner nitride film 140. The outer insulating spacer 146 may be in contact with a lower end of the inner nitride film 140 with the inner insulating spacer 142 between the outer insulating spacer 146 and the inner nitride film 140. The outer insulating spacer 146 may extend in the vertical direction (the Z direction), in which the sidewall of the direct contact DC extends. The outer insulating spacer 146 may be separated from the direct contact DC by the inner nitride film 140 and the inner insulating spacer 142. A portion of the inner nitride film 140 in contact with the buffer layer 122 may be in contact with a sidewall of the outer insulating spacer 146. The gapfill insulating pattern 144 may include a portion arranged between the outer insulating spacer 146 and the inner insulating spacer 142. In some embodiments, the outer insulating spacer 146 may include a silicon nitride film.

At least one side of the outer oxide film 131 may be in contact with an active region ACT adjacent thereto. In an embodiment, a sidewall of the outer oxide film 131 may be in contact with the active region ACT. In some embodiments, although not shown, the sidewall and bottom surface of the outer oxide film 131 may be in contact with the active region ACT. The outer oxide film 131 may be in contact with the isolation film 112 adjacent thereto. The outer oxide film 131 may be between the active region ACT and the inner nitride film 140. Accordingly, the inner nitride film 140 may be separated from the active region ACT adjacent thereto by the outer oxide film 131. The outer oxide film 131 may overlap a portion of the active region ACT in the vertical direction (the Z direction). The outer oxide film 131 may be in contact with the lower end portion of the contact plug 150. The outer oxide film 131 may overlap the contact plug 150 in the vertical direction (the Z direction) and may include a portion facing the first direct contact DC1.

The outer oxide film 131 may include an oxide film, for example, a silicon oxide film. The outer oxide film 131 may be formed by selective oxidation with respect to a direct contact hole DCH. A portion of a film exposed by the direct contact hole DCH may be substituted by the outer oxide film 131 through the selective oxidation. In an embodiment, a portion of the active region ACT exposed by the direct contact hole DCH may be substituted by the outer oxide film 131. The outer oxide film 131 in contact with the active region ACT may include the same element as the active region ACT. In an embodiment, when the active region ACT includes a doped polysilicon film, the outer oxide film 131 may include a silicon oxide film.

For example, in the case where the direct contact hole DCH exposes a portion of the active region ACT and the outer oxide film 131 is not on the exposed portion of the active region ACT, the exposed portion of the active region ACT may be etched when the upper conductive layer 134, the middle conductive layer 132, the lower conductive layer 130, and the direct contact DC are partially etched by using the insulating capping pattern 136 as an etch mask. As a result, the direct contact hole DCH may expand toward the active region ACT, and therefore, the inner nitride film 140, the inner insulating spacer 142, and the gapfill insulating pattern 144, each of which is in the direct contact hole DCH, may overlap with a portion of the active region ACT. At this time, a defect may occur such that the contact plug 150 is not connected to the active region ACT because the contact plug 150 may not extend through the inner nitride film 140, the inner insulating spacer 142, and the gapfill insulating pattern 144.

According to the present disclosure, the active region ACT exposed by the direct contact hole DCH may be covered or overlapped with the outer oxide film 131, which is formed by selective oxidation with respect to the direct contact hole DCH, and accordingly, the active region ACT may not be etched through the direct contact hole DCH when the upper conductive layer 134, the middle conductive layer 132, the lower conductive layer 130, and the direct contact DC are partially etched by using the insulating capping pattern 136 as an etch mask. Accordingly, the contact plug 150 may extend through the inner nitride film 140, the inner insulating spacer 142, and the gapfill insulating pattern 144 because the direct contact hole DCH does not expand toward the active region ACT. Consequently, a defect in which the contact plug 150 is not connected to the active region ACT may be prevented. According to the related art, the width of the direct contact hole DCH in the first horizontal direction (the X direction) is limited so as not to expose the active region ACT because a defect in which the contact plug 150 is not connected to the active region ACT may occur, as described above. However, according to the present disclosure, the contact plug 150 may be connected to the active region ACT even when a portion of the active region ACT is exposed by the direct contact hole DCH, and thus, a process margin for the direct contact hole DCH may be secured regardless of the position of the active region ACT. In addition, the width of the direct contact hole DCH in the first horizontal direction (the X direction) may be sufficiently secured, and accordingly, the distance between the direct contact DC and the contact plug 150 may be secured such that a defect in which the direct contact DC is electrically connected to the contact plug 150 may be prevented.

In embodiments, a portion of the inner insulating spacer 142 above the gapfill insulating pattern 144 may have a different thickness than a portion of the inner insulating spacer 142 in contact with the gapfill insulating pattern 144. For example, a portion of the inner insulating spacer 142 above the gapfill insulating pattern 144 may be thicker than the other portion of the inner insulating spacer 142. The portion of the inner insulating spacer 142 above the gapfill insulating pattern 144 may have a substantially constant thickness in the vertical direction (the Z direction). For example, the portion of the inner insulating spacer 142 above the gapfill insulating pattern 144 may have a thickness of about 10 Å to about 30 Å in the first horizontal direction (the X direction).

Each of the inner nitride film 140, the inner insulating spacer 142, and the outer insulating spacer 146 may extend in the second horizontal direction (the Y direction) to be parallel with the bit line BL.

A metal silicide film 172 may be formed on a plurality of contact plugs 150. Subsequently, a plurality of conductive landing pads LP may be respectively formed above the metal silicide film 172. The conductive landing pads LP may be respectively connected to the contact plugs 150 through the metal silicide film 172. Each of the conductive landing pads LP may extend from a space between two adjacent insulating capping patterns 136 to the top surface of the two adjacent insulating capping patterns 136 so as to vertically overlap a portion of a bit line BL. Each of the conductive landing pads LP may include a conductive barrier film 174 and a conductive layer 176.

In embodiments, the metal silicide film 172 may include, but is not limited to, cobalt silicide, nickel silicide, or manganese silicide. In embodiments, the metal silicide film 172 may be omitted. The conductive barrier film 174 may have a Ti/TiN stack structure. The conductive layer 176 may include doped polysilicon metal, metal silicide, conductive metal nitride, or a combination thereof. For example, the conductive layer 176 may include tungsten (W). Each of the conductive landing pads LP may have an island pattern shape from a top view. The conductive landing pads LP may be electrically insulated from each other by an insulating film 180 filling a space around the conductive landing pads LP. Although it is illustrated that a triple-conductive layer structure of the metal silicide film 172, the conductive barrier film 174, and the conductive layer 176 is arranged on each of the contact plugs 150, the present disclosure is not limited thereto. For example, only a single conductive layer may be arranged on each of the contact plugs 150.

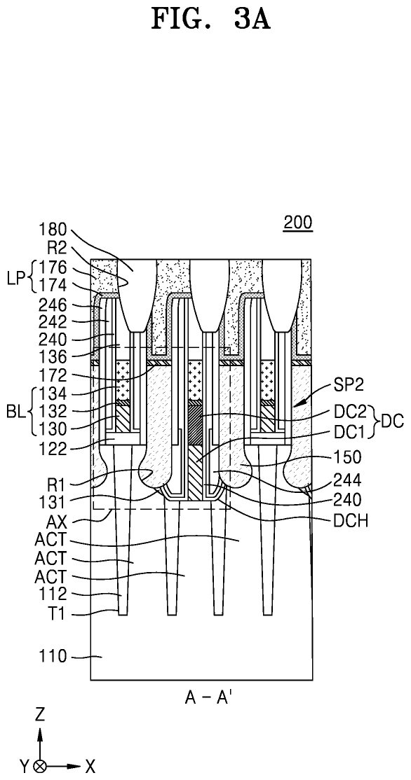

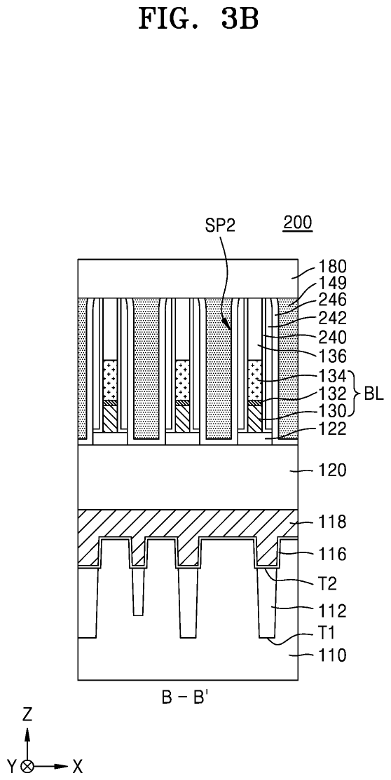

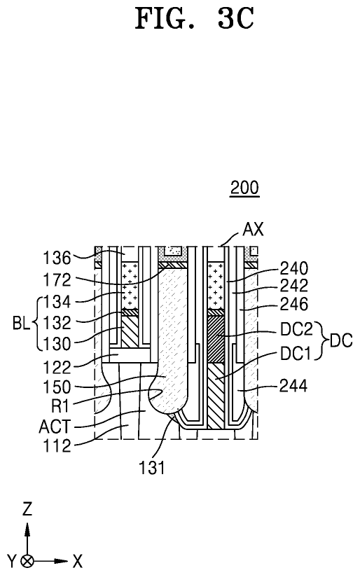

FIGS. 3A-3C show cross-sectional views of an integrated circuit device 200 according to some embodiments. Some elements in a portion corresponding to a dashed line region AX in FIG. 3A are illustrated in an enlarged manner.

Referring to FIG. 3, the integrated circuit device 200 may have substantially the same configuration as the integrated circuit device 100 of FIG. 2. However, the integrated circuit device 200 may include a plurality of spacer structures SP2 instead of the spacer structures SP1. The width of each of the spacer structures SP2 in the first horizontal direction (the X direction) may be less than that of each of the spacer structures SP1 in the first horizontal direction (the X direction).

Each of the spacer structures SP2 may include an inner nitride film 240, an inner insulating spacer 242, a gapfill insulating pattern 244, and an outer insulating spacer 246.

The inner nitride film 240 may be in contact with a sidewall of a direct contact DC and a sidewall of a lower conductive layer 130 of a bit line BL. The inner nitride film 240 may include a portion between the direct contact DC and the gapfill insulating pattern 244. The inner nitride film 240 may include a portion in contact with a lower end portion of a contact plug 150. The inner nitride film 240 may extend in the vertical direction (the Z direction) along respective sidewalls of a middle conductive layer 132 and an upper conductive layer 134 of the bit line BL. The inner nitride film 240 may also extend along respective sidewalls of the middle conductive layer 132 and the upper conductive layer 134 that are on the direct contact DC. The inner nitride film 240 may include a nitride film, for example, a silicon nitride film.

The inner insulating spacer 242 may be in contact with a sidewall of the inner nitride film 240. The bottom surface of the inner insulating spacer 242 may be surrounded by the inner nitride film 240. The inner insulating spacer 242 may extend in the vertical direction (the Z direction) on the sidewall of the inner nitride film 240. The inner insulating spacer 242 may be between the bit line BL and the outer insulating spacer 246. The inner insulating spacer 242 may be surrounded by the outer insulating spacer 246 and the inner nitride film 240 covering or overlapping the bit line BL. The inner insulating spacer 242 may include a portion arranged between the direct contact DC and the gapfill insulating pattern 244. The inner insulating spacer 242 may include a portion in contact with the lower end portion of the contact plug 150.

The gapfill insulating pattern 244 may be between the lower end portion of the contact plug 150 and the direct contact DC. A sidewall of the gapfill insulating pattern 244 may be covered or overlapped with the lower end portion of the contact plug 150. The other sidewall and bottom surface of the gapfill insulating pattern 244 may be surrounded by the inner insulating spacer 242. The gapfill insulating pattern 244 may face the direct contact DC with the inner nitride film 240 and the inner insulating spacer 242 between the gapfill insulating pattern 244 and the direct contact DC in the first horizontal direction (the X direction).

The inner nitride film 240 may surround the lower end portions of the inner insulating spacer 242 and the gapfill insulating pattern 244 and be in contact with the bottom surface of the contact plug 150. The inner insulating spacer 242 may surround the lower end portion of the gapfill insulating pattern 244 and be in contact with the bottom surface of the contact plug 150.

The inner nitride film 240 may be in contact with the respective sidewalls of the middle conductive layer 132 and the upper conductive layer 134 of the bit line BL and a sidewall of an insulating capping pattern 136. The inner insulating spacer 242 may extend along the sidewall of the inner nitride film 240. A portion of the inner insulating spacer 242 above the gapfill insulating pattern 244 may have a different thickness than the other portion of the inner insulating spacer 242. For example, the portion of the inner insulating spacer 242 above the gapfill insulating pattern 244 may be thicker than the other portion of the inner insulating spacer 242.

The outer insulating spacer 246 may cover a sidewall of the contact plug 150 adjacent thereto. The outer insulating spacer 246 may be between the inner insulating spacer 242 and the contact plug 150. The outer insulating spacer 246 may be separated from the bit line BL by the inner nitride film 240 and the inner insulating spacer 242. The outer insulating spacer 246 may be separated from the direct contact DC by the inner nitride film 240 and the inner insulating spacer 242. A portion of the inner nitride film 240 in contact with a buffer layer 122 may be in contact with a sidewall of the outer insulating spacer 246. The inner insulating spacer 242 may be surrounded by the outer insulating spacer 246 and the inner nitride film 240. In some embodiments, the outer insulating spacer 246 may include a silicon nitride film.

An outer oxide film 131 may cover or overlap a portion of a sidewall of an active region ACT adjacent thereto. The outer oxide film 131 may be on a sidewall of a direct contact hole DCH. The outer oxide film 131 may be surrounded by the active region ACT and the inner nitride film 240. The outer oxide film 131 may overlap a portion of the active region ACT adjacent thereto. The outer oxide film 131 may be in contact with the lower end portion of the contact plug 150.

The direct contact hole DCH may include a sidewall in contact with the outer oxide film 131 and an opposite sidewall not in contact with the outer oxide film 131. The sidewall of the direct contact hole DCH may extend through the active region ACT adjacent thereto. The opposite sidewall of the direct contact hole DCH may not extend through an active region ACT adjacent thereto. For example, the opposite sidewall of the direct contact hole DCH may be separated from the active region ACT adjacent thereto.

An inner nitride film 240, an inner insulating spacer 242, and a gapfill insulating pattern 244, which are included in each of a plurality of spacer structures SP2, may be spaced apart from an active region ACT that is adjacent to the spacer structures SP2, with an outer oxide film 131 therebetween. In addition, an inner nitride film 240, an inner insulating spacer 242, and a gapfill insulating pattern 244, which are included in each of a plurality of spacer structures SP2, may be spaced apart from an active region ACT that is adjacent to the spacer structures SP2, with an isolation film 112 therebetween. In an embodiment, when a first active region ACT connected to a first direct contact DC1 and a second active region ACT and a third active region ACT, which are separated from each other by the first active region ACT, are defined among the plurality of active regions ACT and a first contact plug 150 connected to the second active region ACT and a second contact plug 150 connected to the third active region ACT are defined among the plurality of contact plugs 150, the outer oxide film 131 may be in contact with the second active region ACT and the inner nitride film 240 may be separated from the second active region ACT by the outer oxide film 131 or may be separated from the third active region ACT by the isolation film 112. This is because the direct contact hole DCH is formed to be more biased to one side than to the other. For example, the direct contact hole DCH may expose an active region ACT only at one side among a plurality of active regions ACT adjacent to the sidewalls of the direct contact hole DCH and may not expose an active region ACT at the other side.

The outer oxide film 131 may include an oxide film, for example, a silicon oxide film. The outer oxide film 131 may be formed by selective oxidation with respect to a direct contact hole DCH. A portion of a film exposed by the direct contact hole DCH may be substituted by the outer oxide film 131 through the selective oxidation. In an embodiment, a portion of an active region ACT exposed by the direct contact hole DCH may be substituted by the outer oxide film 131. For example, in the case where the direct contact hole DCH exposes a portion of the active region ACT and the outer oxide film 131 is not on the portion of the active region ACT exposed by the direct contact hole DCH, the exposed active region ACT may be etched during a subsequent etching process. Because the direct contact hole DCH may be expanded toward the active region ACT by the subsequent etching process, an inner nitride film 240, an inner insulating spacer 242, and a gapfill insulating pattern 244 may overlap with a portion of the active region ACT. At this time, a defect may occur such that the contact plug 150 is not connected to the active region ACT because the contact plug 150 may not extend through the inner nitride film 240, the inner insulating spacer 242, and the gapfill insulating pattern 244. According to the present disclosure, the active region ACT exposed by the direct contact hole DCH may be covered or overlapped with the outer oxide film 131, and accordingly, the exposed active region ACT may not be etched in a subsequent etching process. Accordingly, the contact plug 150 may extend through the inner nitride film 240, the inner insulating spacer 242, and the gapfill insulating pattern 244 to be connected to the active region ACT because the direct contact hole DCH does not expand toward the active region ACT in the subsequent etching process. Consequently, a defect in which the contact plug 150 is not connected to the active region ACT may be prevented from occurring when the direct contact hole DCH exposes a portion of the active region ACT.

The detailed configurations of the inner nitride film 240, the inner insulating spacer 242, the gapfill insulating pattern 244, and the outer insulating spacer 246 are substantially the same as those of the inner nitride film 140, the inner insulating spacer 142, the gapfill insulating pattern 144, and the outer insulating spacer 146 described above with reference to FIG. 2 above.

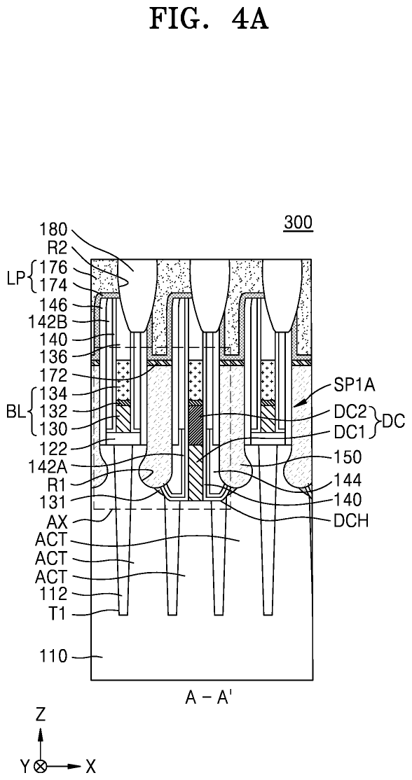

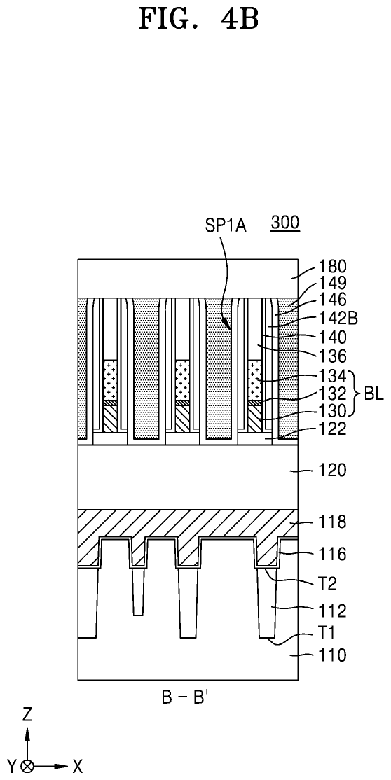

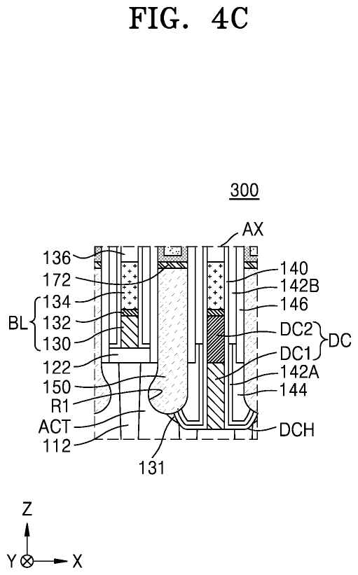

FIGS. 4A-4C cross-sectional views of an integrated circuit device 300 according to some embodiments. Some elements in a portion corresponding to a dashed line region AX in FIG. 4A are illustrated in an enlarged manner.

Referring to FIG. 4, the integrated circuit device 300 may have substantially the same configuration as the integrated circuit device 100 of FIG. 2. However, the integrated circuit device 300 may include a plurality of spacer structures SP1A instead of the spacer structures SP1. Hereinafter, redundant descriptions of the integrated circuit device 100 given above with reference to FIG. 2 above are brief or omitted, and configurations of the integrated circuit device 300 that are different from those of the integrated circuit device 100 are described in detail.

Each of the spacer structures SP1A may include an inner nitride film 140, an inner insulating spacer including a first inner insulating spacer 142A and a second inner insulating spacer 142B, a gapfill insulating pattern 144, and an outer insulating spacer 146.

The inner insulating spacer (including the first and second inner insulating spacers 142A and 142B) may extend in the vertical direction (the Z direction) on a sidewall of the inner nitride film 140. The inner insulating spacer (including the first and second inner insulating spacers 142A and 142B) may be separated from a bit line BL by the inner nitride film 140. The inner insulating spacer may include the first inner insulating spacer 142A between the gapfill insulating pattern 144 and a first direct contact DC1 and the second inner insulating spacer 142B between the outer insulating spacer 146 and a second direct contact DC2. The bottom surface of the first inner insulating spacer 142A may be surrounded by the inner nitride film 140. The first inner insulating spacer 142A may include a portion between a direct contact DC and the gapfill insulating pattern 144. The first inner insulating spacer 142A may include a portion in contact with a lower end portion of a contact plug 150. The second inner insulating spacer 142B may be between the bit line BL and the outer insulating spacer 146. The first inner insulating spacer 142A may include a silicon oxide film and the second inner insulating spacer 142B may include a silicon oxide film, an air spacer, or a combination thereof.

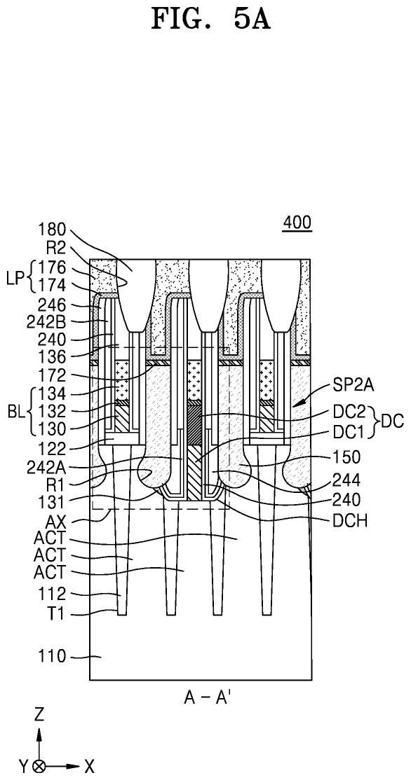

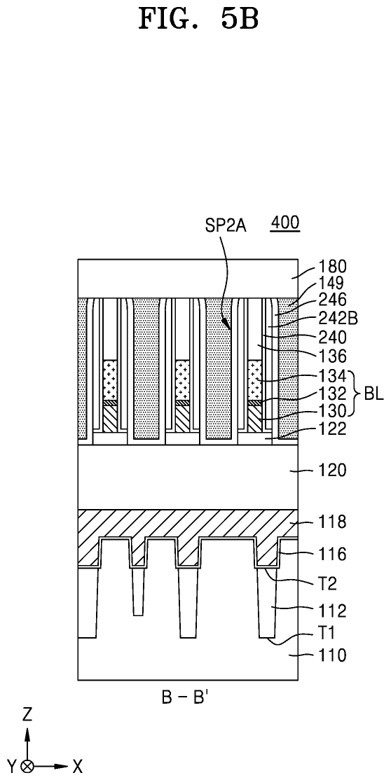

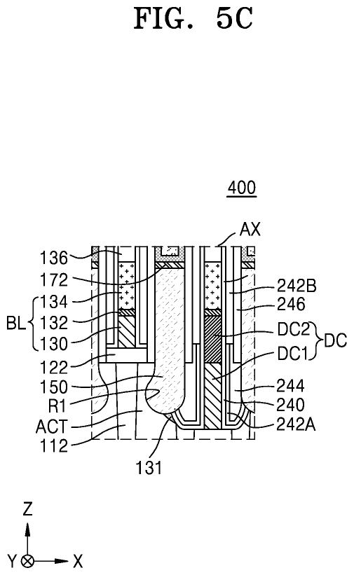

FIGS. 5A-5C show cross-sectional views of an integrated circuit device 400 according to some embodiments. Some elements in a portion corresponding to a dashed line region AX in FIG. 5A are illustrated in an enlarged manner.

The integrated circuit device 400 may have substantially the same configuration as the integrated circuit device 200 of FIG. 3. However, the integrated circuit device 400 may include a plurality of spacer structures SP2A instead of the spacer structures SP2. Hereinafter, redundant descriptions of the integrated circuit device 200 given above with reference to FIG. 3 above are brief or omitted, and configurations of the integrated circuit device 400 that are different from those of the integrated circuit device 200 are described in detail.

Each of the spacer structures SP2A may include an inner nitride film 240, an inner insulating spacer including a first inner insulating spacer 242A and a second inner insulating spacer 242B, a gapfill insulating pattern 244, and an outer insulating spacer 246.

The inner insulating spacer (including the first and second inner insulating spacers 242A and 242B) may extend in the vertical direction (the Z direction) on a sidewall of the inner nitride film 240. The inner insulating spacer (including the first and second inner insulating spacers 242A and 242B) may be separated from a bit line BL by the inner nitride film 240. The inner insulating spacer may include the first inner insulating spacer 242A between the gapfill insulating pattern 244 and a first direct contact DC1 and the second inner insulating spacer 242B between the outer insulating spacer 246 and a second direct contact DC2. The bottom surface of the first inner insulating spacer 242A may be surrounded by the inner nitride film 240. The first inner insulating spacer 242A may include a portion between a direct contact DC and the gapfill insulating pattern 244. The first inner insulating spacer 242A may include a portion in contact with a lower end portion of a contact plug 150. The second inner insulating spacer 242B may be between the bit line BL and the outer insulating spacer 246. The first inner insulating spacer 242A may include a silicon oxide film and the second inner insulating spacer 242B may include a silicon oxide film, an air spacer, or a combination thereof.

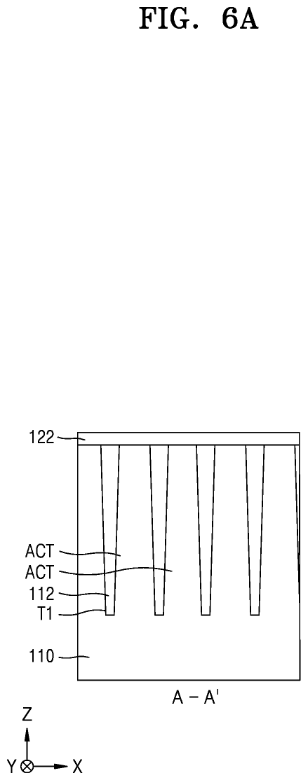

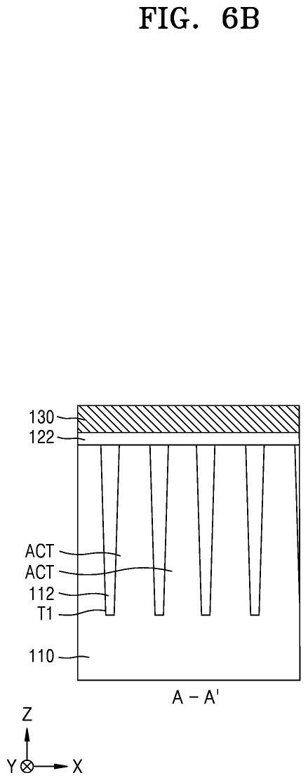

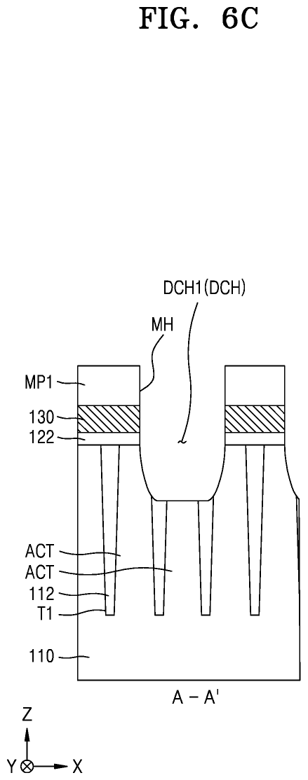

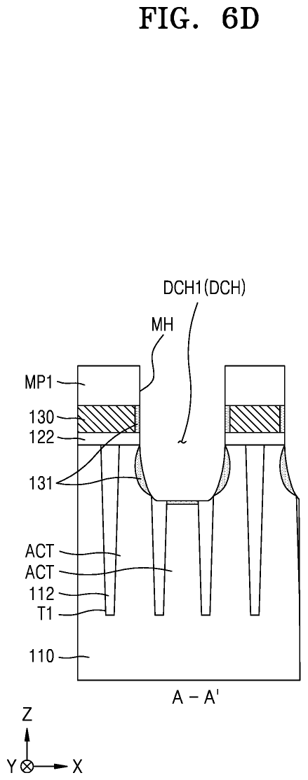

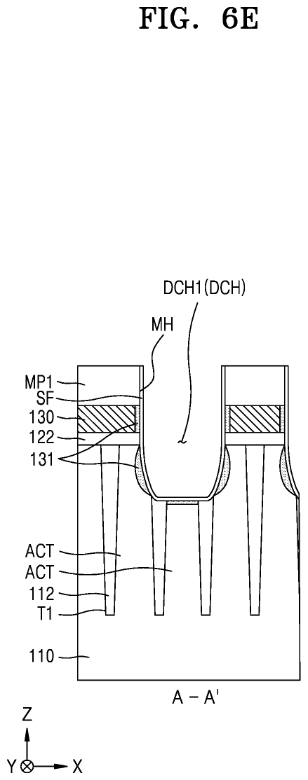

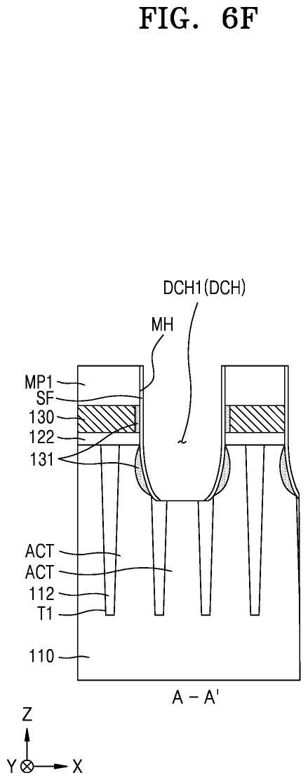

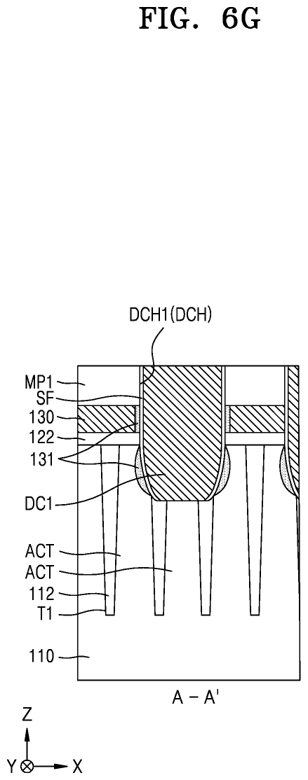

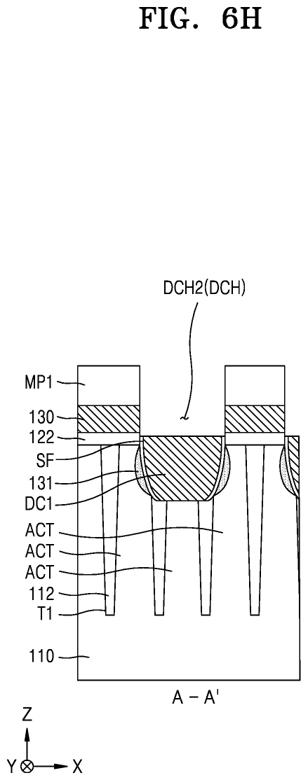

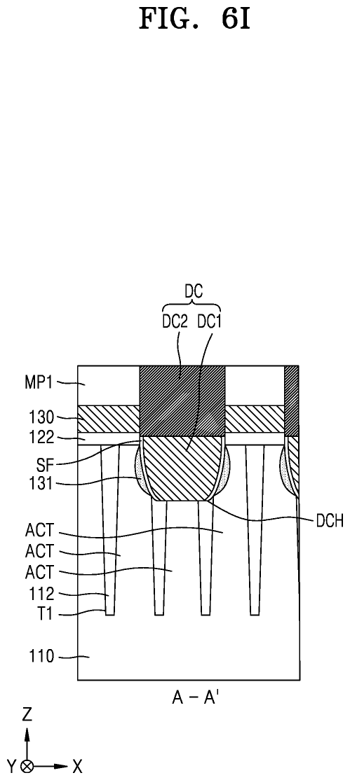

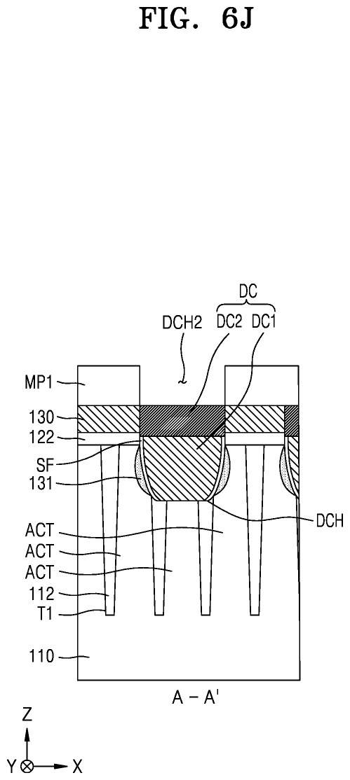

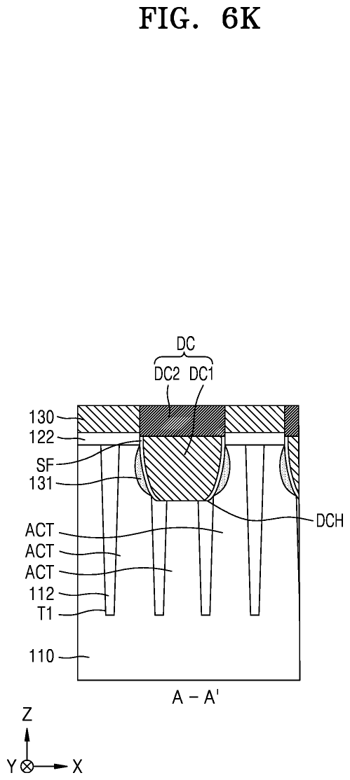

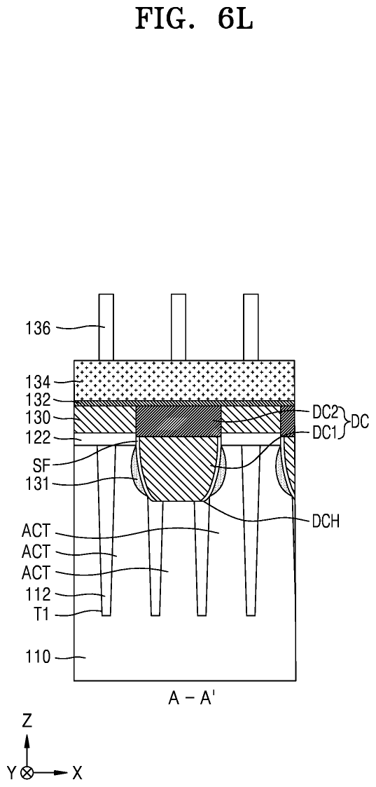

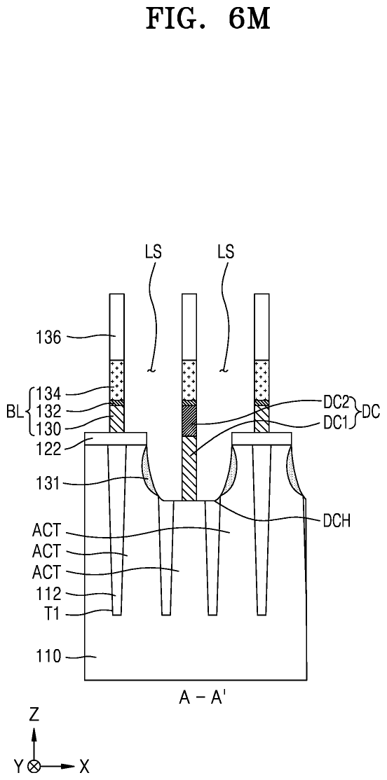

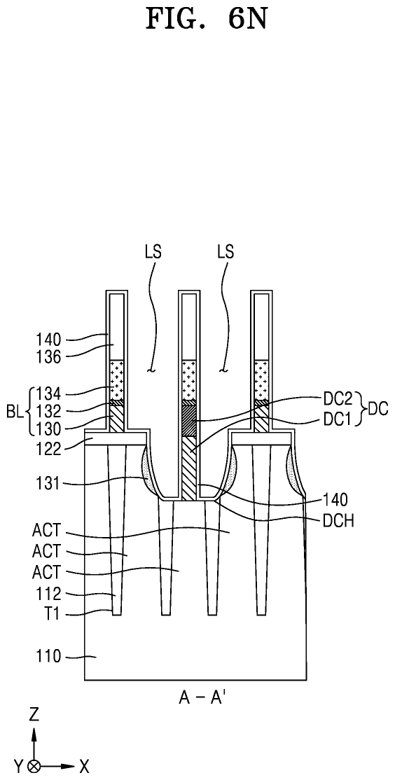

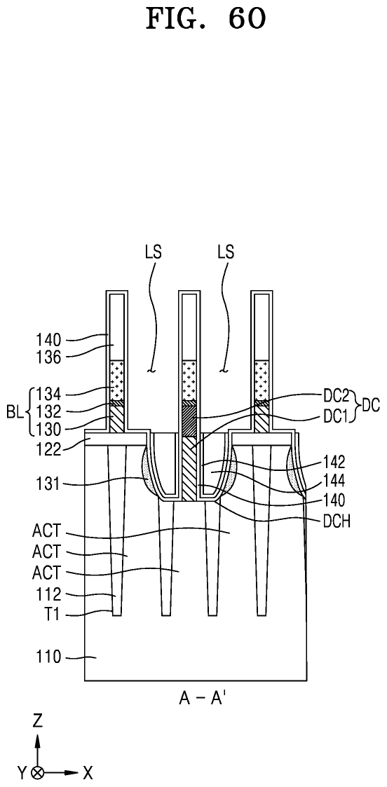

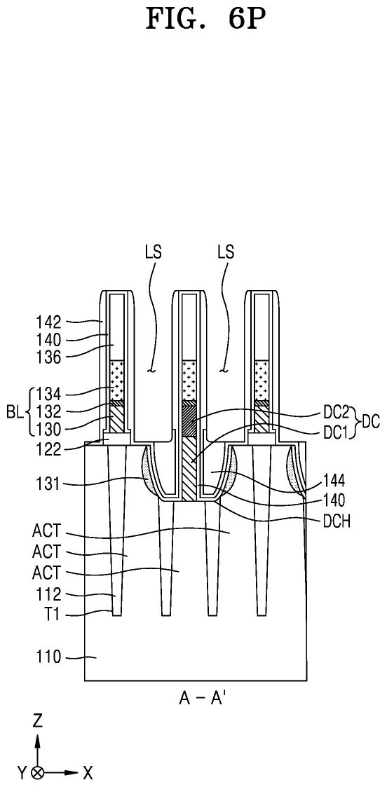

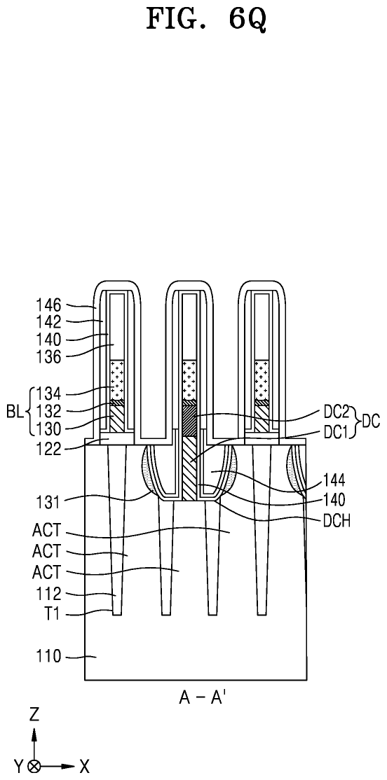

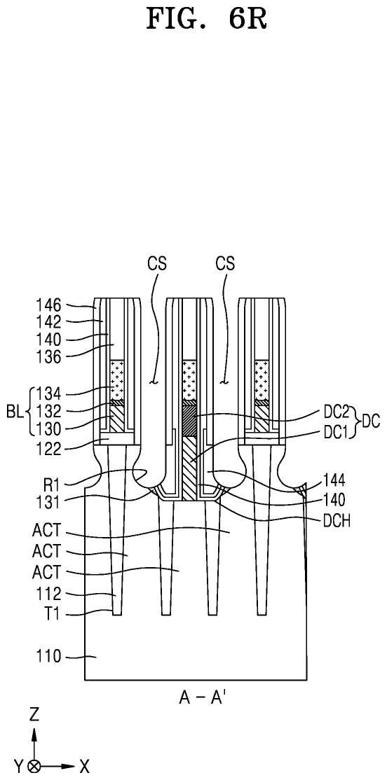

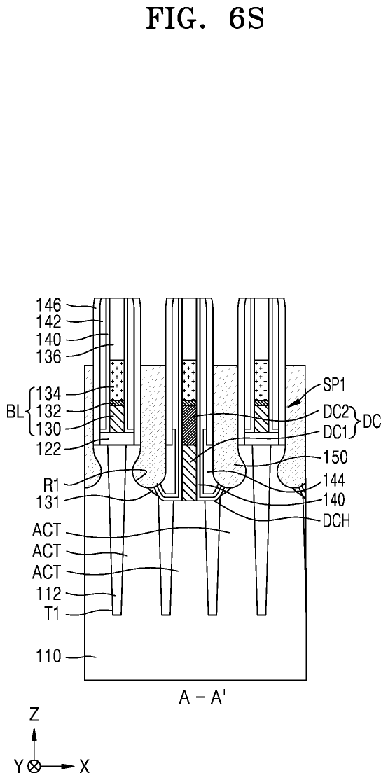

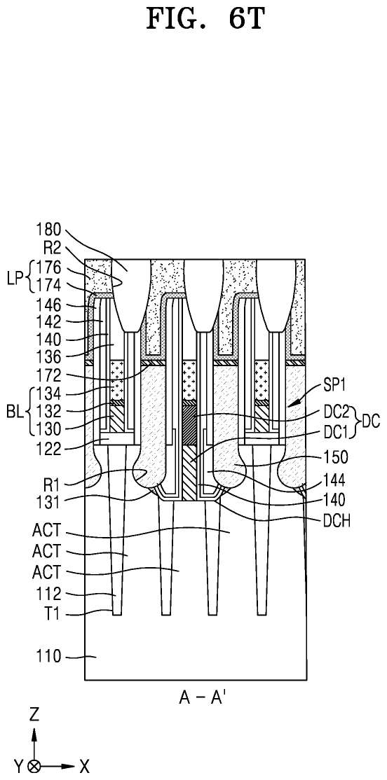

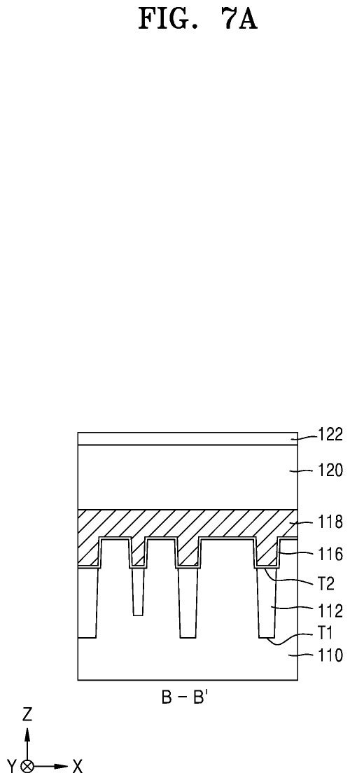

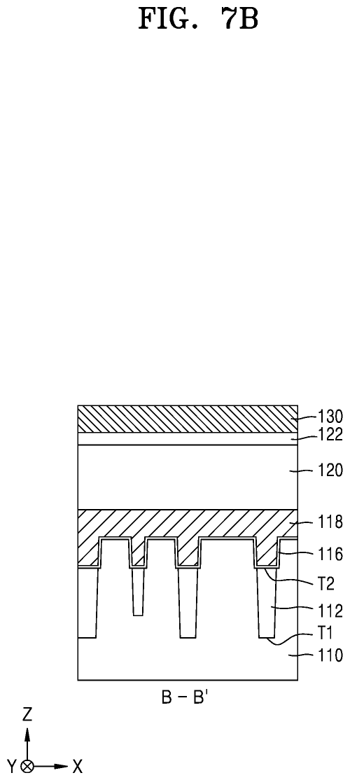

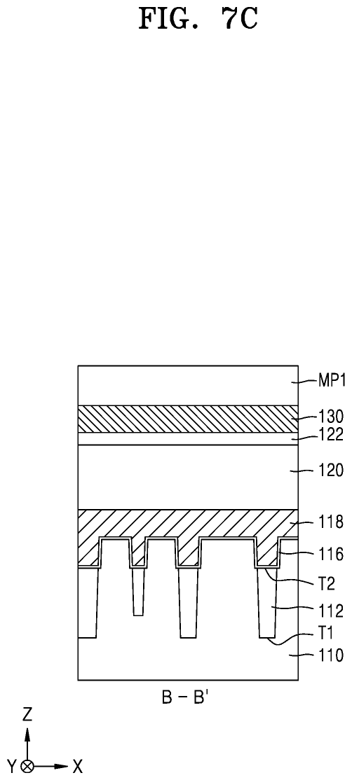

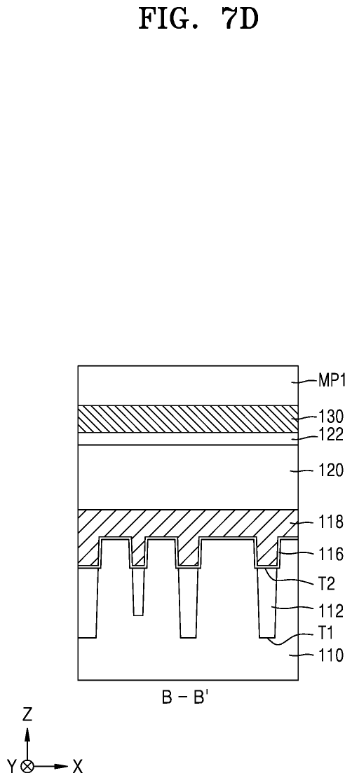

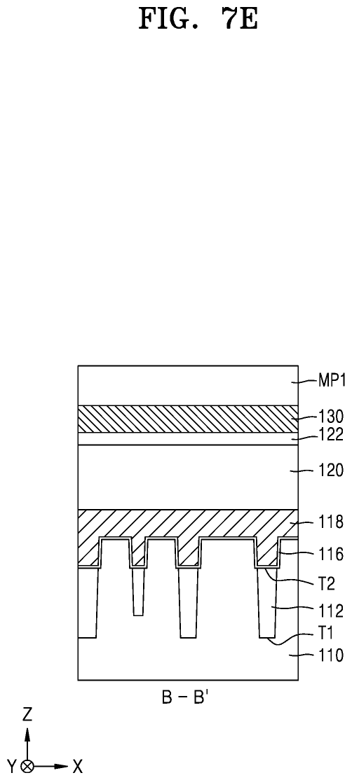

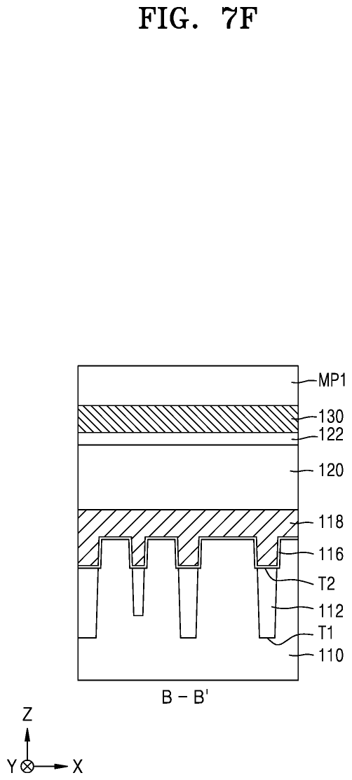

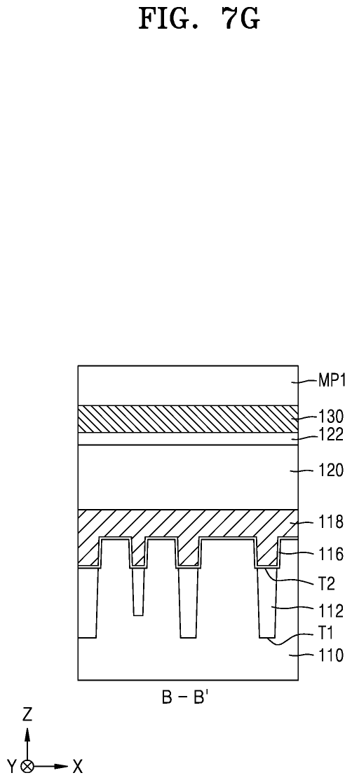

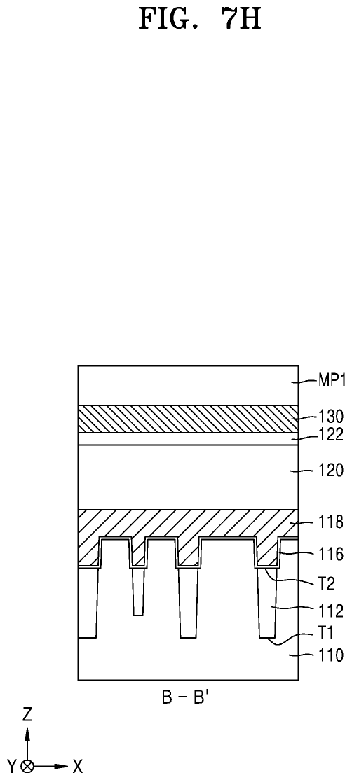

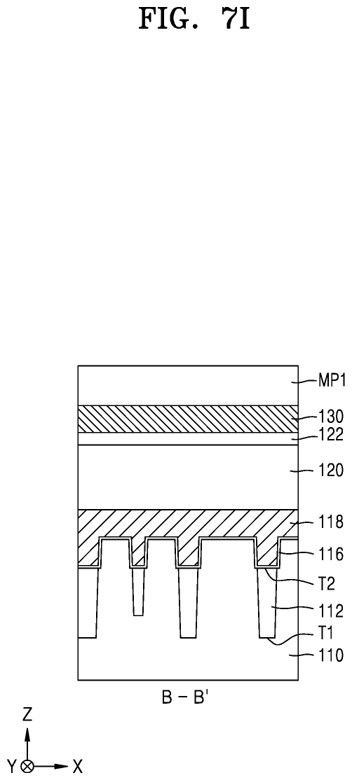

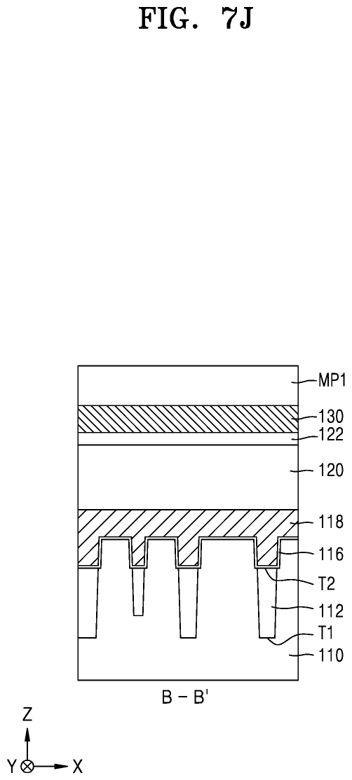

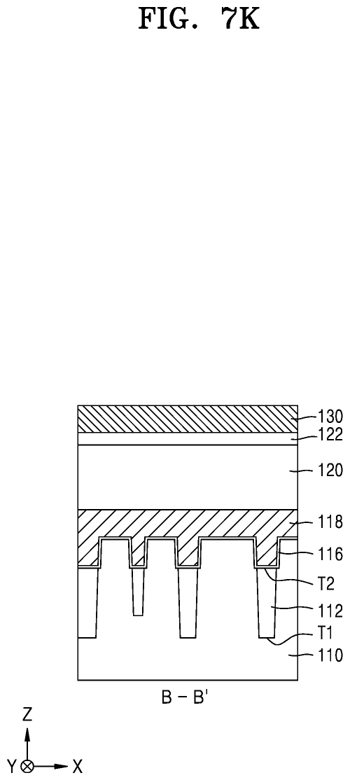

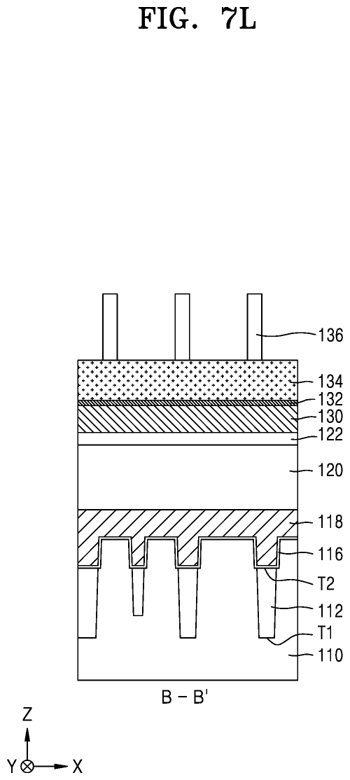

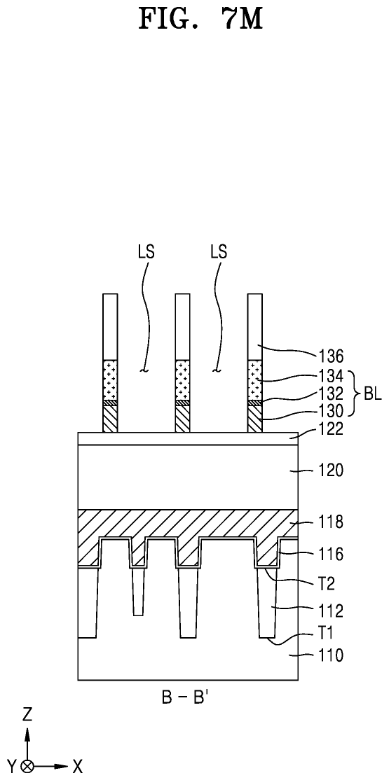

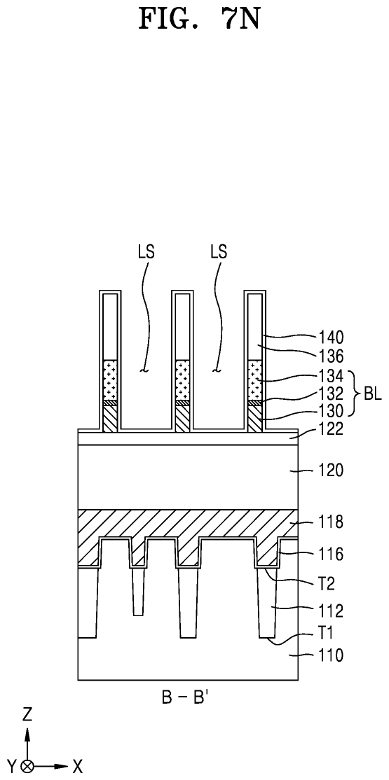

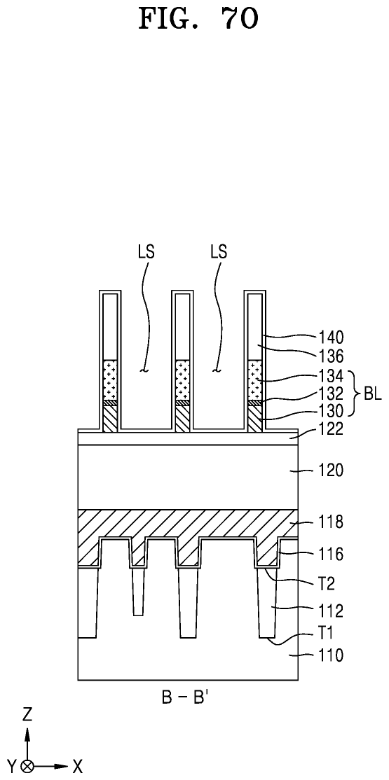

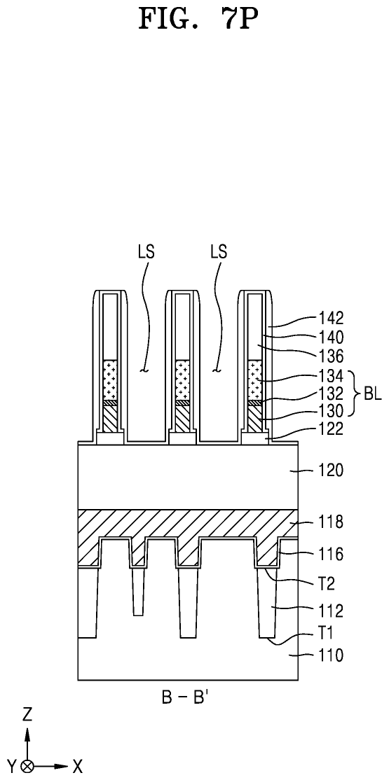

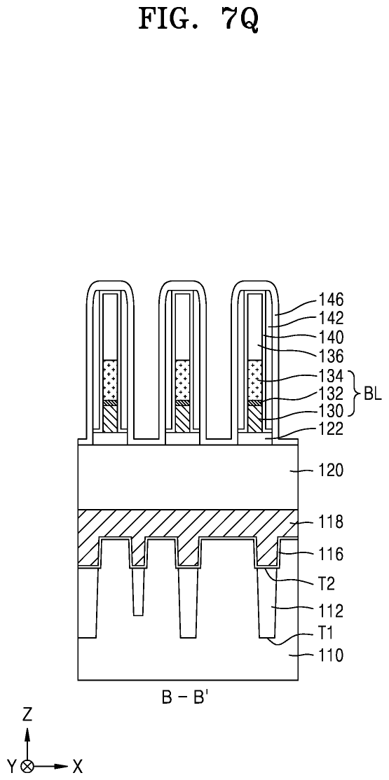

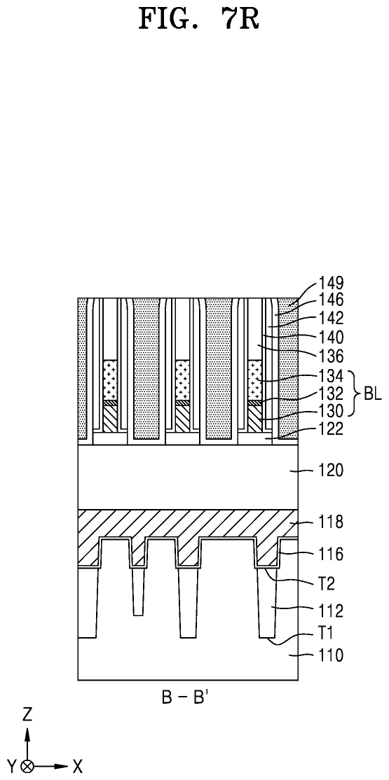

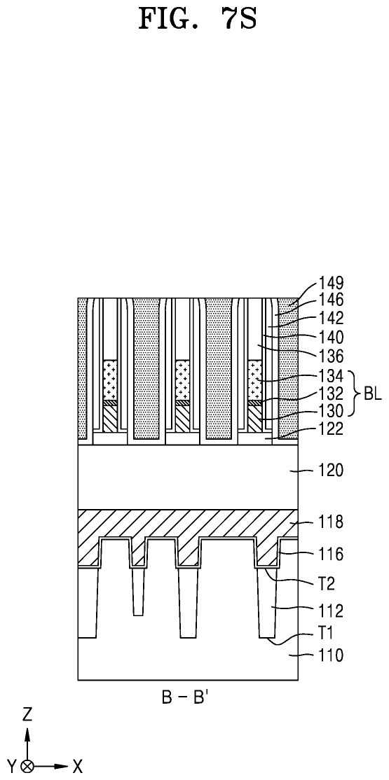

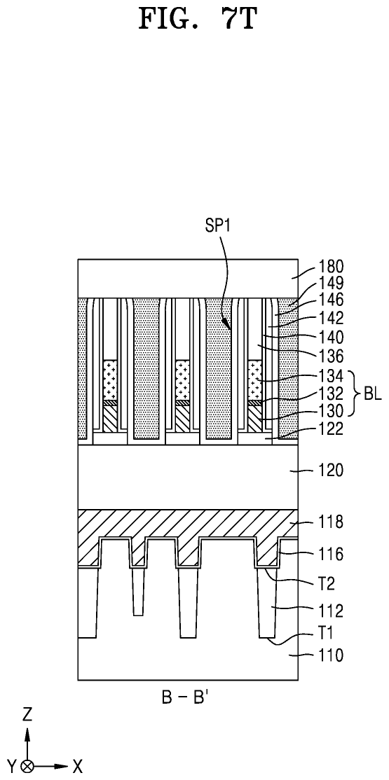

FIGS. 6A to 6T and 7A to 7T are cross-sectional views of stages in a method of manufacturing an integrated circuit device, according to embodiments. FIGS. 6A to 6T show a cross-sectional view of a portion of the cross-section along line A-A′ in FIG. 1 and FIGS. 7A to 7T a cross-sectional view of a portion of the cross-section along line B-B′ in FIG. 1. A method of manufacturing the integrated circuit device 100 of FIG. 2 is described below with reference to FIGS. 6A to 6T and FIGS. 7A to 7T.

Referring to FIGS. 6A and 7A, an isolation trench T1 may be formed in a substrate 110 and an isolation film 112 may be formed in the isolation trench T1. A plurality of active regions ACT may be defined in the substrate 110 by the isolation film 112.

A plurality of word line trenches T2 may be formed in the substrate 110. The word line trenches T2 may extend in the first horizontal direction (the X direction) to be parallel with each other. Each of the word line trenches T2 may have a line shape that intersects the active regions ACT. To form the word line trenches T2 each having a step in the bottom thereof, the isolation film 112 and the substrate 110 may be individually etched by separate etching processes such that the etching depth of the isolation film 112 is different from the etching depth of the substrate 110. After the resultant structure with the word line trenches T2 is cleaned, a gate dielectric film 116, a word line 118, and a buried insulating film 120 may be sequentially formed in each of the word line trenches T2. Before or after a plurality of word lines 118 are formed, ion-implantation may be performed to respectively form a plurality of source/drain regions on the active regions ACT.

A buffer layer 122 may be formed on the substrate 110. The buffer layer 122 may be formed to cover or overlap the top surfaces of the active regions ACT, the top surface of the isolation film 112, and the top surfaces of a plurality of buried insulating films 120. The buffer layer 122 may include, but is not limited to, a first silicon oxide film, a silicon nitride film, and a second silicon oxide film, which are sequentially formed on the substrate 110.

Referring to FIGS. 6B and 7B, a lower conductive layer 130 may be formed on the buffer layer 122. The lower conductive layer 130 may include a doped polysilicon film.

Referring to FIGS. 6C and 7C, after a mask pattern MP1 is formed on the lower conductive layer 130, the lower conductive layer 130 exposed by an opening MH of the mask pattern MP1 and the buffer layer 122, the substrate 110, and the isolation film 112, which are below the lower conductive layer 130, may be partially etched, thereby forming a first direct contact hole DCH1 exposing the active regions ACT of the substrate 110. At this time, a portion of an active region ACT may be exposed on a sidewall of the first direct contact hole DCH1. The mask pattern MP1 may include, but is not limited to, an oxide film, a nitride film, or a combination thereof.

Referring to FIGS. 6D and 7D, selective oxidation may be performed in the first direct contact hole DCH1, thereby forming an outer oxide film 131. The outer oxide film 131 may be formed on a sidewall of the lower conductive layer 130 and the active region ACT, which are exposed by the first direct contact hole DCH1. The outer oxide film 131 may have an etch selectivity with respect to the lower conductive layer 130 and the active region ACT. In an embodiment, the selective oxidation may include isotropic oxidation, which has no specific oxidation directivity. During the isotropic oxidation, a portion of the lower conductive layer 130 and a portion of the active region ACT, which are exposed by the first direct contact hole DCH1, may be oxidized, thereby forming the outer oxide film 131. Accordingly, the outer oxide film 131 in contact with the lower conductive layer 130 may include the same element as the lower conductive layer 130. In an embodiment, when the lower conductive layer 130 includes a doped polysilicon film, the outer oxide film 131 may include a silicon oxide film. The outer oxide film 131 in contact with the active region ACT may include the same element as the active region ACT. In an embodiment, when the active region ACT includes a doped polysilicon film, the outer oxide film 131 may include a silicon oxide film. The outer oxide film 131 may be formed with a relatively smaller thickness such that the lower conductive layer 130 and the active region ACT may remain with a sufficient thickness.

Referring to FIGS. 6E and 7E, a sacrificial film SF may be formed in the first direct contact hole DCH1. In detail, the sacrificial film SF may be formed along the inner wall of the first direct contact hole DCH1 to cover or overlap the outer oxide film 131.

Referring to FIGS. 6F and 7F, a portion of the outer oxide film 131 and a portion of the sacrificial film SF, which overlap the bottom surface of the first direct contact hole DCH1 in the vertical direction (the Z direction), may be etched in the resultant structure of FIGS. 6E and 7E such that the active region ACT may be exposed at the bottom of the first direct contact hole DCH1. Accordingly, the sacrificial film SF may remain on the sidewall of the first direct contact hole DCH1.

Referring to FIGS. 6G and 7G, a first direct contact DC1 may be formed in the first direct contact hole DCH1. To form the first direct contact DC1, a doped polysilicon film may be formed in the first direct contact hole DCH1 and above the lower conductive layer 130 to have a sufficient thickness to fill the first direct contact hole DCH1 and then partially removed such that the doped polysilicon film remains only in the first direct contact hole DCH1.

Referring to FIGS. 6H and 7H, a second direct contact hole DCH2 may be formed by etching a portion of each of the lower conductive layer 130, the buffer layer 122 below the lower conductive layer 130, the first direct contact DC1, the sacrificial film SF, and the outer oxide film 131 in the resultant structure of FIGS. 6G and 7G. The second direct contact hole DCH2 may have a sufficient width in the first horizontal direction (the X direction) and a sufficient length in the vertical direction (the Z direction) such that the outer oxide film 131 formed on the lower conductive layer 130 may be removed. The sidewall of the lower conductive layer 130 may be exposed by the second direct contact hole DCH2.

Referring to FIGS. 6I and 7I, a second direct contact DC2 may be formed in the second direct contact hole DCH2. To form the second direct contact DC2, a doped polysilicon film may be formed in the second direct contact hole DCH2 and above the lower conductive layer 130 to a sufficient thickness to fill the second direct contact hole DCH2 and then partially removed such that the doped polysilicon film remains only in the second direct contact hole DCH2.

Referring to FIGS. 6J, 7J, 6K, and 7K, a portion of the second direct contact DC2 overlapping the mask pattern MP1 may be removed and the mask pattern MP1 may be removed.

Referring to FIGS. 6L and 7L, a middle conductive layer 132, an upper conductive layer 134, and a plurality of insulating capping patterns 136 may be sequentially formed on the lower conductive layer 130 and a direct contact DC. Each of the insulating capping patterns 136 may be configured as a line pattern extending in the second horizontal direction (the Y direction).

Referring to FIGS. 6M and 7M, a plurality of bit lines BL may be formed on the substrate 110 by partially etching each of the upper conductive layer 134, the middle conductive layer 132, the lower conductive layer 130, and the direct contact DC by using the insulating capping patterns 136 as etch masks. The bit lines BL may be formed by remaining portions of the lower conductive layer 130, the middle conductive layer 132, and the upper conductive layer 134. After the bit lines BL are formed, a portion of the first direct contact hole DCH1 may be re-exposed around the first direct contact DC1 and a portion of the second direct contact hole DCH2 may be re-exposed around the second direct contact DC2. A line space LS extending long in the second horizontal direction (the Y direction) may be defined between two adjacent bit line structures each including a bit line BL and an insulating capping pattern 136.

Referring to FIGS. 6N and 7N, an inner nitride film 140 may be formed to conformally cover or overlap the exposed surface of the resultant structure of FIGS. 6M and 7M. The inner nitride film 140 may be formed to be in contact with the buffer layer 122, the lower conductive layer 130, the middle conductive layer 132, the upper conductive layer 134, the insulating capping patterns 136, the first direct contact DC1, and the second direct contact DC2.

To form the inner nitride film 140, chemical vapor deposition (CVD) or atomic layer deposition (ALD) may be used. The inner nitride film 140 may be formed to have a substantially constant thickness on the sidewall of each of the bit lines BL and the sidewall of each of the insulating capping patterns 136 in the vertical direction (the Z direction). In embodiments, the inner nitride film 140 may be formed to be in contact with the outer oxide film 131. In some embodiments, when a direct contact hole DCH is formed by an etching process to be biased to one side, the inner nitride film 240 in FIG. 3 may be formed instead of the inner nitride film 140. For example, when the direct contact hole DCH exposes an active region ACT only at one side among a plurality of active regions ACT adjacent to the sidewalls of the direct contact hole DCH and does not expose an active region ACT at the other side, the outer oxide film 131 may not be formed on the active region ACT at the other side and the active region ACT at the other side may be in direct contact with the inner nitride film 240.

Referring to FIGS. 6O and 7O, an inner insulating spacer 142 covering or overlapping the sidewalls of the first and second direct contacts DC1 and DC2 may be formed along the inner wall of the direct contact hole DCH having the inner nitride film 140 formed thereon in the resultant structure of FIGS. 6N and 7N. A gapfill insulating pattern 144 may be formed to fill the remaining space of the direct contact hole DCH having the inner insulating spacer 142 formed therein.

To form the inner insulating spacer 142 and the gapfill insulating pattern 144, a silicon oxide film may be formed on the inner nitride film 140 of the resultant structure of FIGS. 6N and 7N and a silicon nitride film may be formed on the silicon oxide film. The silicon oxide film and the silicon nitride film may be partially removed and may thus remain only in the direct contact hole DCH. To form the silicon oxide film and the silicon nitride film, CVD or ALD may be used.

Referring to FIGS. 6P and 7P, an inner insulating spacer film may be formed by using CVD or ALD to conformally cover the exposed surface of the resultant structure of FIGS. 6O and 7O, and then a plurality of inner insulating spacers 142 may be formed by anisotropically etching the inner insulating spacer film. While the inner insulating spacer film is being anisotropically etched to form the inner insulating spacers 142, a portion of the buffer layer 122 and a portion of the inner nitride film 140 covering the buffer layer 122 may be removed. As a result, the substrate 110, the inner nitride film 140, the inner insulating spacer 142 in the direct contact hole DCH, and the gapfill insulating pattern 144 may be partially exposed at the bottom of each of a plurality of line spaces LS. The plurality of inner insulating spacers 142 may be on the inner nitride film 140 and may respectively cover or overlap the sidewalls of the bit lines BL and the sidewalls of the insulating capping patterns 136.

The inner insulating spacers 142 may include a material that is different from the material of the inner nitride film 140 and the material of the gapfill insulating pattern 144. The inner insulating spacers 142 may include a material having an etch selectivity with respect to each of the inner nitride film 140 and the gapfill insulating pattern 144. For example, the inner insulating spacers 142 may include a silicon oxide film.

Referring to FIGS. 6Q and 7Q, an outer insulating spacer 146 may be formed to conformally cover the resultant structure of FIGS. 6P and 7P. The outer insulating spacer 146 may include a material having an etch selectivity with respect to the inner insulating spacers 142. For example, the outer insulating spacer 146 may include a silicon nitride film. CVD or ALD may be used to form the outer insulating spacer 146.

Referring to FIGS. 6R and 7R, a plurality of insulating fences 149 may be formed to be separated from each other in each line space LS defined by the outer insulating spacer 146 between two adjacent bit lines BL in the resultant structure of FIG. 6Q and may thus divide the line space LS into a plurality of contact spaces CS.

Each of the insulating fences 149 may be formed on the word line 118 to overlap the word line 118. The insulating fences 149 may include a silicon nitride film. In embodiments, the insulating capping patterns 136 may be partially consumed while the insulating fences 149 are being formed, and thus, the height of the insulating capping patterns 136 may decrease.

Thereafter, structures exposed by the contact spaces CS may be partially removed, thereby forming a plurality of recesses R1 respectively exposing active regions ACT of the substrate 110 between the plurality of bit lines BL. Anisotropic etching or a combination of anisotropic etching and isotropic etching may be used to form the recesses R1. For example, the recesses R1 may be formed by anisotropically etching a portion of the outer insulating spacer 146 exposed by the contact spaces CS between the bit lines BL and a portion of the substrate 110 below the outer insulating spacer 146 and isotropically etching a portion of each of the active regions ACT of the substrate 110, which is exposed as a result of the anisotropic etching. The recesses R1 may respectively be in communication with the contact spaces CS. While an etching process is being performed to form the contact spaces CS, each of the outer oxide film 131, the inner nitride film 140, the inner insulating spacer 142, and the gapfill insulating pattern 144 that are in a region adjacent to the top surface of the substrate 110 may be partially consumed.

A portion of an active region ACT of the substrate 110, a portion of the outer oxide film 131, a portion of the inner nitride film 140, a portion of the inner insulating spacer 142, and a portion of the gapfill insulating pattern 144 may be exposed by each of the recesses R1.

Referring to FIGS. 6S and 7S, a plurality of contact plugs 150 may be formed to respectively fill the recesses R1 between the bit lines BL and respectively fill portions of the contact spaces CS between the bit lines BL.

When each of the upper conductive layer 134, the middle conductive layer 132, the lower conductive layer 130, and the direct contact DC is partially etched by using the insulating capping patterns 136 as etch masks in FIGS. 6M and 7M, an active region ACT exposed by the direct contact hole DCH may also be etched in the case where the outer oxide film 131 is not formed. When the active region ACT is etched, the direct contact hole DCH may be enlarged such that a recess R1 may not expose the active region ACT of the substrate 110 due to the inner nitride film 140, the inner insulating spacer 142, and the gapfill insulating pattern 144. Therefore, a defect in which a contact plug 150 is not connected to the active region ACT of the substrate 110 may occur. According to the present disclosure, because the active region ACT is not exposed by the direct contact hole DCH due to the outer oxide film 131, the direct contact hole DCH may be prevented from being enlarged, and accordingly, a defect in which the contact plug 150 is not connected to the active region ACT of the substrate 110 may be prevented. Due to the outer oxide film 131, the contact plug 150 may be connected to the active region ACT of the substrate 110 even when the active region ACT is exposed by the direct contact hole DCH, and thus, a process margin for the direct contact hole DCH may be secured regardless of the position of the active region ACT. In addition, the width of the direct contact hole DCH in the first horizontal direction (the X direction) may be sufficiently secured, and accordingly, the distance between the direct contact DC and the contact plug 150 may be secured such that a defect in which the direct contact DC is electrically connected to the contact plug 150 may be prevented.

Referring to FIGS. 6T and 7T, a metal silicide film 172 and a plurality of conductive landing pads LP may be formed on the plurality of contact plugs 150 respectively exposed by the plurality of contact spaces CS (see FIGS. 6S and 7S).

Each of the contact plugs 150 and the metal silicide film 172 may form at least a portion of one of the buried contacts BC in FIG. 1. Each of the conductive landing pads LP may be formed on the metal silicide film 172 to fill one of the contact spaces CS and extend to the top surface of one of the insulating capping patterns 136 so as to vertically overlap a portion of one of the plurality of bit lines BL. Each of the conductive landing pads LP may include a conductive barrier film 174 and a conductive layer 176.

To form the conductive landing pads LP, the conductive barrier film 174 and the conductive layer 176 may be formed on the entire surface of the resultant structure having the metal silicide film 172 formed thereon, and a mask pattern (not shown) exposing a portion of the conductive layer 176 may be formed on the conductive layer 176. Thereafter, upper recesses R2 may be formed by etching the conductive layer 176, the conductive barrier film 174, and insulating films therearound by using the mask pattern as an etch mask. The mask pattern may include a silicon nitride film but is not limited thereto.

Each of the conductive landing pads LP may have an island pattern shape. A portion of each conductive landing pad LP may extend in a horizontal direction outside one of the contact spaces CS and may form one of the conductive landing pads LP in FIG. 1.

The conductive landing pads LP may be electrically insulated from each other by filling the upper recesses R2 around the conductive landing pads LP with an insulating film 180. Thereafter, a plurality of lower electrodes that may be electrically connected to the conductive landing pads LP, respectively, may be formed on the insulating film 180.

In embodiments, in the processes described with reference to FIG. 6T, after the upper recesses R2 are formed around the conductive landing pads LP and before the upper recesses R2 are filled with the insulating film 180, at least a portion of the silicon oxide film of each of the plurality of inner insulating spacers 142 may be removed through one of the upper recesses R2.

For example, the silicon oxide film of each inner insulating spacer 142 may be completely removed through one of the upper recesses R2 such that the inner insulating spacer 142 may be configured as an air spacer.

While the present disclosure has been particularly shown and described with reference to embodiments thereof, it will be understood that various changes in form and details may be made therein without departing from the spirit and scope of the following claims.

What is claimed is:

1. An integrated circuit device comprising:
a substrate that comprises a plurality of active regions, wherein the plurality of active regions comprise a first active region and a second active region that is adjacent to the first active region;
a bit line that extends on the substrate in a horizontal direction;
a first direct contact connected to the first active region;
a second direct contact between the first direct contact and the bit line;
an inner nitride film connected to a sidewall of the first direct contact and a sidewall of the second direct contact;
an isolation film between the first active region and the second active region; and
an outer oxide film that is connected to at least one surface of the second active region and between the inner nitride film and the second active region.

2. The integrated circuit device of claim 1, further comprising:
a contact plug connected to the second active region and that extends in a vertical direction on an upper surface of the substrate;
a gapfill insulating pattern between a lower end portion of the contact plug and the first direct contact; and
an inner insulating spacer connected to the inner nitride film,
wherein a first portion of the inner nitride film and a first portion of the inner insulating spacer are between the first direct contact and the gapfill insulating pattern.

3. The integrated circuit device of claim 2, wherein a second portion of the inner insulating spacer has a different thickness than the first portion of the inner insulating spacer, and wherein a second distance between the second portion of the inner insulating spacer and the substrate is greater than a first distance between the first portion of the inner insulating spacer and the substrate.

4. The integrated circuit device of claim 2, wherein:
a first portion of the gapfill insulating pattern is between the lower end portion of the contact plug and the second direct contact and faces the second direct contact, and
a second portion of the gapfill insulating pattern that faces the first direct contact has a different thickness than the first portion of the gapfill insulating pattern.

5. The integrated circuit device of claim 1, further comprising:
a contact plug connected to the second active region and that extends in a vertical direction on an upper surface of the substrate;
a gapfill insulating pattern between a lower end portion of the contact plug and the first direct contact; and
an inner insulating spacer connected to the inner nitride film,
wherein the inner nitride film comprises a first portion between the first direct contact and the gapfill insulating pattern and a second portion connected to the lower end portion of the contact plug, and
the inner insulating spacer comprises a first portion between the inner nitride film and the gapfill insulating pattern and a second portion connected to the lower end portion of the contact plug.

6. The integrated circuit device of claim 5, wherein the outer oxide film is connected to the lower end portion of the contact plug.

7. The integrated circuit device of claim 1, further comprising:
a contact plug connected to the second active region that extends in a vertical direction on an upper surface of the substrate;
a gapfill insulating pattern between a lower end portion of the contact plug and the first direct contact;
an outer insulating spacer on the gapfill insulating pattern and a sidewall of the contact plug; and
an inner insulating spacer connected to the inner nitride film,
wherein the inner nitride film and the inner insulating spacer are between the outer insulating spacer and the second direct contact.

8. The integrated circuit device of claim 1, further comprising:
an inner insulating spacer, wherein the inner nitride film is between the inner insulating spacer and the bit line; and
an outer insulating spacer connected to a lower end portion of the inner nitride film, wherein the inner insulating spacer is between the outer insulating spacer and the inner nitride film,
wherein the inner nitride film at least partially surrounds a lower surface of the inner insulating spacer.

9. The integrated circuit device of claim 1, wherein the outer oxide film comprises a silicon oxide film.

10. The integrated circuit device of claim 1, comprising:
a contact plug connected to the second active region and that extends in a vertical direction on an upper surface of the substrate;
a gapfill insulating pattern between a lower end portion of the contact plug and the first direct contact; and
an outer insulating spacer on the gapfill insulating pattern and a sidewall of the contact plug,
wherein each of the gapfill insulating pattern and the outer insulating spacer comprises a silicon nitride film.

11. The integrated circuit device of claim 10, further comprising an inner insulating spacer connected to the inner nitride film,
wherein the inner insulating spacer comprises a silicon oxide film.

12. The integrated circuit device of claim 10, further comprising:
a first inner insulating spacer between the gapfill insulating pattern and the first direct contact; and
a second inner insulating spacer between the outer insulating spacer and the second direct contact,
wherein the first inner insulating spacer comprises a silicon oxide film, and
the second inner insulating spacer comprises a silicon oxide film, an air spacer, or a combination thereof.

13. An integrated circuit device comprising:
a substrate that comprises a plurality of active regions, wherein the plurality of active regions comprise a first active region and a second active region that is adjacent to the first active region;
a plurality of bit lines on the substrate and separated from each other in a first horizontal direction, wherein the plurality of bit lines extend in a second horizontal direction that intersects the first horizontal direction;
a first direct contact connected to the first active region;
a second direct contact between the first direct contact and a first bit line from among the plurality of bit lines;
a contact plug connected to the second active region and that extends in a vertical direction on an upper surface of the substrate; and
a spacer structure between the first bit line and the contact plug,
wherein the spacer structure comprises:
an inner nitride film connected to a sidewall of the first direct contact and a sidewall of the second direct contact; and
an outer oxide film on the second active region in the vertical direction and connected to at least one surface of the second active region, and
the outer oxide film is between the inner nitride film and the second active region.

14. The integrated circuit device of claim 13, wherein each of the plurality of bit lines comprises a lower conductive layer including a doped polysilicon film and an upper conductive layer including a metal.

15. The integrated circuit device of claim 13, wherein the spacer structure further comprises a gapfill insulating pattern between a lower end portion of the contact plug and the first direct contact,
the inner nitride film comprises a portion between the first direct contact and the gapfill insulating pattern, and
the outer oxide film is on the contact plug in the vertical direction and comprises a portion that faces the first direct contact.

16. The integrated circuit device of claim 13, further comprising:
a third active region among the plurality of active regions, wherein the first active region is between the second active region and the third active region; and
an isolation film between the first active region and the second active region and between the second active region and the third active region,
wherein the isolation film is between the inner nitride film and the third active region.

17. An integrated circuit device comprising:
a substrate that comprises a first active region and a second active region;
a bit line that extends on the substrate in a horizontal direction;
a first direct contact connected to the first active region;
a second direct contact between the first direct contact and the bit line;
a contact plug connected to the second active region; and
a spacer structure between the bit line and the contact plug, wherein the spacer structure comprises:
an inner nitride film connected to a sidewall of the first direct contact and a sidewall of the second direct contact;
an inner insulating spacer connected to the inner nitride film;
an outer oxide film on the second active region and connected to the second active region, wherein the outer oxide film is between the inner nitride film and the second active region; and
a gapfill insulating pattern between the contact plug and the first direct contact.

18. The integrated circuit device of claim 17, wherein a first portion of the inner nitride film and a first portion of the inner insulating spacer are between the first direct contact and the gapfill insulating pattern.

19. The integrated circuit device of claim 18, wherein a second portion of the inner insulating spacer has a different thickness than the first portion of the inner insulating spacer, and wherein a second distance between the second portion of the inner insulating spacer and the substrate is greater than a first distance between the first portion of the inner insulating spacer and the substrate.

20. The integrated circuit device of claim 17, further comprising:
a third active region on the substrate, wherein the first active region is between the second active region and the third active region; and
an isolation film between the first active region and the second active region and between the second active region and the third active region, wherein the isolation film is between the inner nitride film and the third active region.
